(19) United States
(12) Patent Application Publication
(10) Pub. No.: US 2025/0220915 A1
(43) Pub. Date: Jul. 3, 2025

(54) SEMICONDUCTOR DEVICE AND ELECTRONIC SYSTEM INCLUDING SEMICONDUCTOR DEVICE

(71) Applicant: Samsung Electronics Co., Ltd., Suwon-si (KR)

(72) Inventors: Seung Min Lee, Suwon-si (KR); JONGHO WOO, Suwon-si (KR); Suhwan LIM, Suwon-si (KR); Sangwoo Han, Suwon-si (KR)

(21) Appl. No.: 18/791,709

(22) Filed: Aug. 1, 2024

(30) Foreign Application Priority Data
Dec. 29, 2023 (KR) 10-2023-0197622

(51) Int. Cl. H10B 51/20; H10B 51/30

(52) U.S. Cl. CPC H10B 51/20; H10B 51/30

(57) ABSTRACT

A semiconductor device including a substrate, a gate stacked structure including a plurality of interlayer insulating layers and a plurality of gate electrodes alternately stacked on the substrate, a channel structure extending along a first direction through the gate stacked structure and connected to the substrate, a plurality of conductive patterns surrounding the channel structure and spaced apart from each other at different levels along the first direction, and a plurality of ferroelectric patterns spaced apart from each other and respectively surrounding the conductive patterns at each of the different levels along the first direction. At each of the different levels along the first direction, a ferroelectric pattern is disposed between a conductive pattern and a gate electrode in a radial direction of the channel structure, and a thickness of the ferroelectric pattern in the first direction is thinner than a thickness in the first direction of the gate electrode.

### CROSS-REFERENCE TO RELATED APPLICATION

This application claims priority under 35 U.S.C. § 119 to and the benefit of Korean Patent Application No. 10-2023-0197622 filed in the Korean Intellectual Property Office on Dec. 29, 2023, the entire content of which is incorporated herein by reference.

### BACKGROUND

### Field

The present disclosure relates to a semiconductor device and an electronic system including the semiconductor device.

### Description of the Related Art

Semiconductor memory devices may be generally classified into volatile memory devices and nonvolatile memory devices. The volatile memory devices lose their stored data when their power supplies are interrupted, and may include, for example, dynamic random access memories (DRAMs) and static random access memories (SRAMs). Meanwhile, the nonvolatile memory devices maintain their stored data even when their power supplies are interrupted, and may include, for example, programmable ROMs (PROMs), erasable PROMs (EPROMs), electrically EPROMs (EEPROMs), and flash memory devices. In addition, to meet an increasing demand for a semiconductor memory device with high performance and low power consumption, next-generation nonvolatile semiconductor memory devices, such as magnetic random access memory (MRAM), phase-change random access memory (PRAM), and ferroelectric random access memory (FeRAM) devices, are being developed. To provide a semiconductor device with high integration density and high performance, various studies using semiconductor devices with different properties are being conducted.

### SUMMARY

The present disclosure attempts to provide a semiconductor device that may improve reliability and a data storage system including the semiconductor device.

An embodiment of the present disclosure provides a semiconductor device including: a substrate; a gate stacked structure including a plurality of interlayer insulating layers and a plurality of gate electrodes alternately stacked on the substrate; a channel structure extending along a first direction through the gate stacked structure and connected to the substrate; a plurality of conductive patterns surrounding the channel structure and spaced apart from each other at different levels along the first direction; and a plurality of ferroelectric patterns spaced apart from each other and each respectively surrounding the conductive patterns at each of the different levels along the first direction, wherein, at each of the different levels along the first direction, a ferroelectric pattern is disposed between a conductive pattern and a gate electrode in a radial direction of the channel structure, and wherein, at each of the different levels along the first direction, a thickness of the ferroelectric pattern in the first direction is thinner than a thickness in the first direction of the gate electrode.

Another embodiment provides a semiconductor device including: a substrate; a gate stacked structure including a plurality of interlayer insulating layers and a plurality of gate electrodes alternately stacked on the substrate; a channel structure extending along a first direction through the gate stacked structure and connected to the substrate; a plurality of conductive patterns surrounding the channel structure and spaced apart from each other at different levels along the first direction; and a plurality of ferroelectric patterns spaced apart from each other and each respectively surrounding and in contact with the conductive patterns at each of the different levels along the first direction, wherein, at each of the different levels along the first direction, a lower surface of the ferroelectric pattern is disposed farther from the substrate than a lower surface of the conductive pattern contacting the ferroelectric pattern, and wherein, at each of the different levels along the first direction, an upper surface of the ferroelectric pattern is disposed closer to the substrate than an upper surface of the conductive pattern contacting the ferroelectric pattern.

Another embodiment provides an electronic system including: a main substrate; a semiconductor device on the main substrate; and a controller electrically connected to the semiconductor device on the main substrate, wherein the semiconductor device includes a substrate, a gate stacked structure including a plurality of interlayer insulating layers and a plurality of gate electrodes alternately stacked on the substrate, a channel structure extending along a first direction through the gate stacked structure and connected to the substrate, a plurality of conductive patterns surrounding the channel structure and spaced apart from each other at different levels along the first direction, and a plurality of ferroelectric patterns spaced apart from each other and each respectively surrounding the conductive patterns at each of the different levels along the first direction, wherein, at each of the different levels along the first direction, a ferroelectric pattern is disposed between a conductive pattern and a gate electrode in a radial direction of the channel structure, and wherein, at each of the different levels along the first direction, a thickness of the ferroelectric pattern in the first direction is thinner than a thickness in the first direction of the gate electrode.

According to the embodiments, it is possible to improve the reliability of a semiconductor device.

### BRIEF DESCRIPTION OF THE DRAWINGS

FIG. 1 illustrates a schematic cross-sectional view of a semiconductor device according to an embodiment.

FIG. 2 illustrates an enlarged cross-sectional view of an example of a channel structure included in the semiconductor device illustrated in FIG. 1.

FIG. 3 illustrates an enlarged view of a portion of a cell array area of the semiconductor device illustrated in FIG. 1.

FIG. 4 illustrates a perspective view of a channel structure of FIG. 3.

FIG. 5 illustrates a portion indicated by C in FIG. 3.

FIG. 6 illustrates a ferroelectric pattern and a channel insulating layer of FIG. 4 separately.

FIG. 7 illustrates another embodiment having the same cross-section as FIG. 5.

FIG. 8 illustrates another embodiment having the same cross-section as FIG. 5.

FIG. 9 illustrates another embodiment having the same cross-section as FIG. 7.

FIG. 10 to FIG. 18 illustrate manufacturing methods of a semiconductor device according to an embodiment.

FIG. 19 to FIG. 27 illustrate manufacturing methods of a semiconductor device according to an embodiment.

FIG. 28 to FIG. 37 illustrate manufacturing methods of a semiconductor device according to an embodiment.

FIG. 38 illustrates a schematic cross-sectional view of a semiconductor device according to an additional embodiment.

FIG. 39 schematically illustrates an electronic system including a semiconductor device according to an example embodiment.

FIG. 40 illustrates a schematic perspective view of an electronic system including a semiconductor device according to an example embodiment.

FIG. 41 and FIG. 42 respectively illustrate a schematic cross-sectional view of a semiconductor package according to an example embodiment.

### DETAILED DESCRIPTION

The present disclosure will be described more fully hereinafter with reference to the accompanying drawings, in which embodiments of the invention are shown. As those skilled in the art would realize, the described embodiments may be modified in various different ways, all without departing from the spirit or scope of the present disclosure.

In the drawings, the thicknesses of layers, films, panels, regions, areas, etc., are exaggerated for clarity. Like reference numerals designate like elements throughout the specification. It will be understood that when an element such as a layer, film, region, area or substrate is referred to as being “on” or “above” another element, it can be directly on the other element or intervening elements may also be present. In contrast, when an element is referred to as being “directly on” another element, there are no intervening elements present.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

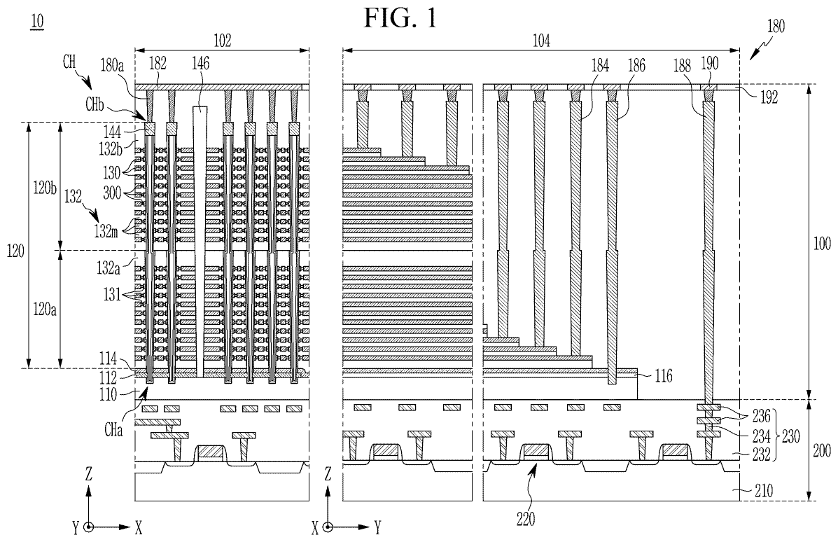

Hereinafter, a semiconductor device according to an embodiment will be described with reference to FIG. 1 to FIG. 5.

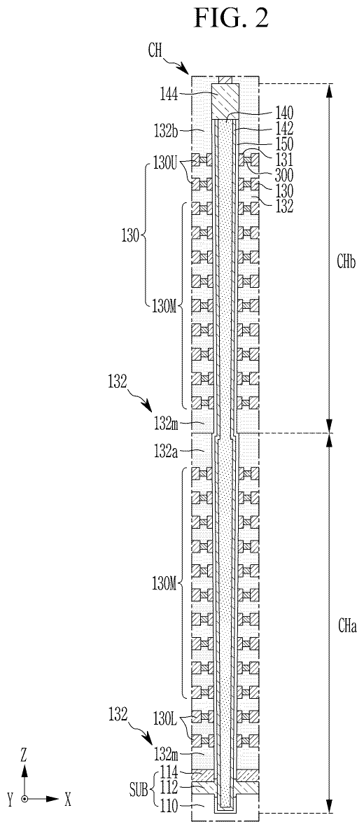

FIG. 1 illustrates a schematic cross-sectional view of a semiconductor device according to an embodiment, and FIG. 2 illustrates an enlarged cross-sectional view of an example of a channel structure included in the semiconductor device illustrated in FIG. 1.

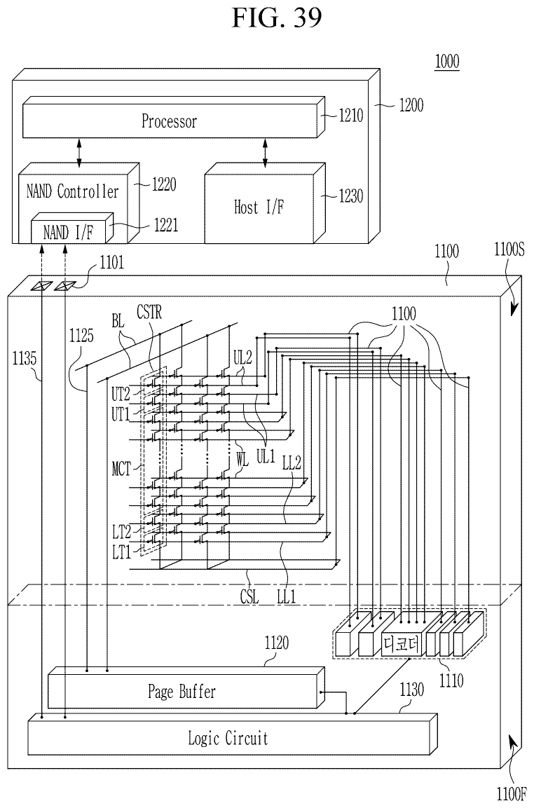

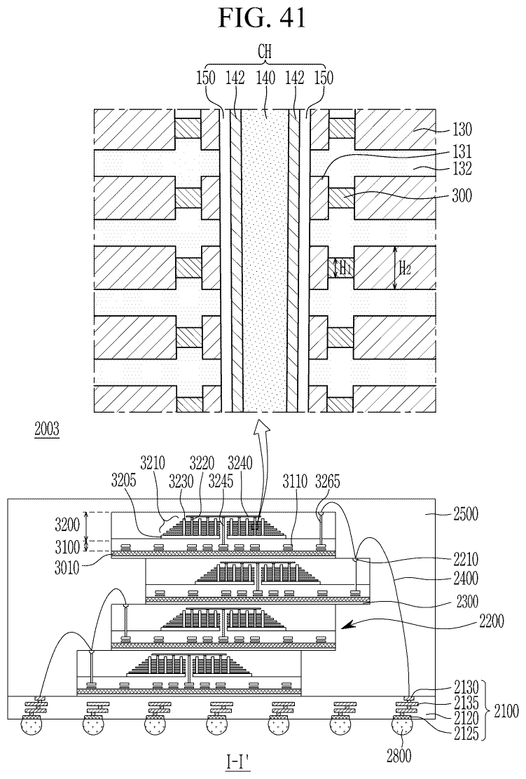

Referring to FIG. 1 and FIG. 2, a semiconductor device 10 according to an embodiment may include a cell area 100 provided with a memory cell structure and a circuit area 200 provided with a peripheral circuit structure that controls an operation of the memory cell structure. For example, the circuit area 200 and the cell area 100 may be portions corresponding to a first structure 1100F and a second structure 1100S of a semiconductor device 1100 included in an electronic system 1000 illustrated in FIG. 39, respectively. Alternatively, the circuit area 200 and the cell area 100 may be portions including a first structure 3100 and a second structure 3200 of a semiconductor chip 2200 illustrated in FIG. 41, respectively.

Here, the circuit area 200 may include a peripheral circuit structure formed on a first substrate 210, and the cell area 100 may include a gate stacked structure 120 and a channel structure CH formed on a second substrate 110 as a memory cell structure. A first wiring portion 230 may be provided in the circuit area 200, and a second wiring portion 180 electrically connected to the memory cell structure may be provided in the cell area 100.

In an example embodiment, the cell area 100 may be disposed on the circuit area 200. According to this, an area corresponding to the circuit area 200 does not need to be secured separately from the cell area 100, so an area of the semiconductor device 10 may be reduced. However, the embodiment is not limited thereto, and the circuit area 200 may be disposed next to the cell area 100. Various other variations are possible.

The circuit area 200 may include the first substrate 210, and a circuit element 220 and the first wiring portion 230 formed on the first substrate 210.

The first substrate 210 may be a semiconductor substrate including a semiconductor material. For example, the first substrate 210 may be a semiconductor substrate made of a semiconductor material, or it may be a semiconductor substrate with a semiconductor layer formed on a base substrate. For example, the first substrate 210 may be made of a single-crystalline or polycrystalline silicon, epitaxial silicon, germanium, silicon-germanium, silicon-on-insulator (SOI), or germanium-on-insulator (GOI).

The circuit elements 220 formed on the first substrate 210 may include various circuit elements that control the operation of the memory cell structure provided in the cell area 100. For example, the circuit element 220 may configure a peripheral circuit structure such as a decoder circuit (reference numeral 1110 in FIG. 39), a page buffer (reference numeral 1120 in FIG. 39), and a logic circuit (reference numeral 1130 in FIG. 39).

The circuit element 220 may include, for example, a transistor, but is not limited thereto. For example, the circuit element 220 may include active elements such as a transistor, as well as passive elements such as a capacitor, a resistor, and an inductor.

The first wiring portion 230 disposed on the first substrate 210 may be electrically connected to the circuit element 220. In an example embodiment, the first wiring portion 230 may include a plurality of wiring layers 236 that are spaced apart from each other with a first insulating layer 232 therebetween and connected to form a desired path by a contact via 234. The wiring layer 236 or the contact via 234 may include various conductive materials, and the first insulating layer 232 may include various insulating materials.

The cell area 100 may include a cell array area 102 and a connection area 104. The gate stacked structure 120 and the channel structure CH may be formed on the second substrate 110 in the cell array area 102. A structure for connecting the gate stacked structure 120 and/or the channel structure CH formed in the cell array area 102 to the circuit area 200 or an external circuit may be disposed in the cell array area 102 and/or the connection area 104.

In the embodiment, the second substrate 110 may include a semiconductor layer including a semiconductor material. For example, the second substrate 110 may be a semiconductor substrate made of a semiconductor material, or it may be a semiconductor substrate with a semiconductor layer formed on a base substrate. For example, the second substrate 110 may be made of silicon, germanium, silicon-germanium, silicon-on-insulator, or germanium-on-insulator. Here, the semiconductor layer included in the second substrate 110 may be doped with p-type or n-type impurities. For example, n-type impurities (for example, phosphorus (P), arsenic (As), and the like) may be doped. However, the embodiment is not limited to the material of the second substrate 110, the conductive material of impurities doped into the semiconductor layer, and the like.

In the cell array area 102, the gate stacked structure 120 including a cell insulating layer 132 and a gate electrode 130 alternately stacked on the first surface (for example, the front surface or the upper surface) of the second substrate 110, and the channel structure CH extending in a direction crossing the second substrate 110 through the gate stacked structure 120 may be formed.

In an example embodiment, horizontal conductive layers 112 and 114 may be disposed between the second substrate 110 and the gate stacked structure 120 in the cell array area 102. The horizontal conductive layers 112 and 114 may serve to electrically connect the channel structure CH and the second substrate 110. For example, the horizontal conductive layers 112 and 114 may include a first horizontal conductive layer 112 disposed on the first surface of the second substrate 110, and may further include a second horizontal conductive layer 114 disposed on the first horizontal conductive layer 112. In a partial area of the connection area 104, the first horizontal conductive layer 112 may not be provided between the second substrate 110 and the gate stacked structure 120, and the horizontal insulating layer 116 may be provided. In the manufacturing process, a portion of the horizontal insulating layer 116 may be replaced with the first horizontal conductive layer 112, and another portion of the horizontal insulating layer 116 disposed in the connection area 104 may remain in the connection area 104.

The first horizontal conductive layer 112 can function as a portion of a common source line of the semiconductor device 10. For example, the first horizontal conductive layer 112 may function as the common source line along with the second substrate 110. As shown in the enlarged view of FIG. 2, the channel structure CH may extend to reach the second substrate 110 through the horizontal conductive layers 112 and 114, and the channel insulating layer 150 may be removed from a portion where the first horizontal conductive layer 112 is disposed, so that the first horizontal conductive layer 112 may be directly connected to the channel layer 142 and may extend around the channel layer 142.

The first and second horizontal conductive layers 112 and 114 may include a semiconductor material (for example, polycrystalline silicon). For example, the first horizontal conductive layer 112 may be a polycrystalline silicon layer doped with impurities, and the second horizontal conductive layer 114 may be a polycrystalline silicon layer doped with impurities or a layer including impurities diffused from the first horizontal conductive layer 112. However, the embodiment is not limited thereto, and the second horizontal conductive layer 114 may be made of an insulating material. Alternatively, the second horizontal conductive layer 114 may not be separately provided.

The gate stacked structure 120 in which the cell insulating layer 132 and the gate electrode 130 are alternately stacked may be disposed on the second substrate 110 (for example, on the first and second horizontal conductive layers 112 and 114 formed on the second substrate 110).

The cell insulating layer 132 may include an interlayer insulating layer 132m disposed between two adjacent gate electrodes 130 in each of a plurality of gate stacked structures 120a and 120b, and upper insulating layers 132a and 132b respectively disposed on the plurality of gate stacked structures 120a and 120b. In the embodiment, thicknesses (i.e., height) of the plurality of cell insulating layers 132 may not all be the same. For example, the thicknesses of the upper insulating layers 132a and 132b may be greater than the thickness of the interlayer insulating layer 132m. For simplicity of illustration, the drawing illustrates that the cell insulating layer 132 is provided as one layer in the connection area 104 without a border. However, one or more insulating layers may have various stacked structures in the connection area 104. The shape and structure of the cell insulating layer 132 may be variously modified according to embodiments.

The gate electrode 130 may include various conductive materials. For example, the gate electrode 130 may include a metal material such as tungsten (W), copper (Cu), and aluminum (Al), a polycrystalline silicon, a metal nitride (for example, titanium nitride (TiN), tantalum nitride (TaN), and the like), or a combination thereof. The cell insulating layer 132 may include various insulating materials. For example, the cell insulating layer 132 may include a silicon oxide, a silicon nitride, a silicon oxynitride, a low dielectric constant material having a smaller dielectric constant than the silicon oxide, or a combination thereof.

In the embodiment, the channel structure CH passing through the gate stacked structure 120 to extend in a direction crossing the second substrate 110 (for example, a vertical direction perpendicular to the second substrate 110) (a Z-axis direction of the drawing) may be formed.

The channel structure CH may include a channel layer 142 and a channel insulating layer 150 disposed on the channel layer 142 between the gate electrode 130 and the channel layer 142. The channel structure CH may further include a core insulating layer 140 disposed inside the channel layer 142, but for another example, the core insulating layer 140 may not be provided. The channel structure CH may further include a channel pad 144 disposed on the channel layer 142 and/or the channel insulating layer 150.

Each of the channel structures CH forms one memory cell string, and a plurality of channel structures CH may be disposed to be spaced apart from each other while forming rows and columns in a plan view. For example, the plurality of channel structures CH may be disposed in various shapes, such as a lattice shape or a zigzag shape, in a plan view. The channel structure CH may have a pillar shape. For example, the channel structure CH may have an inclined side surface so that a width thereof becomes narrower as it approaches the second substrate 110 depending on an aspect ratio when viewed in a cross sectional view. However, the embodiment is not limited thereto, and the disposition, structure, and shape of the channel structure CH may be variously modified.

The channel layer 142 may include a semiconductor material, for example, polysilicon. The core insulating layer 140 may include various insulating materials. For example, the core insulating layer 140 may include a silicon oxide, a silicon nitride, a silicon oxynitride, or a combination thereof. However, the materials of the channel layer 142 and the core insulating layer 140 are not limited thereto.

The channel insulating layer 150 may surround the channel layer 142. For example, the channel insulating layer 150 may extend in the third direction (Z direction) to surround the side surface of the channel layer 142. The channel insulating layer 150 may have a planar shape such as an annular shape.

The channel insulating layer 150 may include an insulating material. For example, the channel insulating layer 150 may include a material such as a silicon oxide, a silicon nitride, or a silicon oxynitride. For example, the channel insulating layer 150 may be formed by stacking a layer including a silicon oxide and a layer including a silicon nitride.

The channel pad 144 may be disposed to cover the upper surface of the core insulating layer 140 and be electrically connected to the channel layer 142. The channel pad 144 may include a conductive material, for example, polycrystalline silicon doped with impurities, but is not limited thereto.

In an example embodiment, the gate stacked structure 120 may include a plurality of gate stacked structures 120a and 120b sequentially stacked on the second substrate 110. As a result, the number of stacked gate electrodes 130 may be increased, thereby increasing the number of memory cells with a stable structure. FIG. 1 illustrates that the gate stacked structure 120 includes the first and second gate stacked structures 120a and 120b. However, the embodiment is not limited thereto, and the gate stacked structure 120 may be configured of one or three or more gate stacked structures.

As described above, when the plurality of gate stacked structures 120a and 120b are provided, the channel structure CH may include a plurality of channel portions CHa and CHb penetrating the plurality of gate stacked structures 120a and 120b, respectively. The plurality of channel portions CHa and CHb may be connected to each other. When viewed in a cross-sectional view, each of the plurality of channel portions CHa and CHb may have an inclined side surface so that a width thereof becomes narrower as it approaches the second substrate 110 according to an aspect ratio, and may be provided with a bent portion due to a width difference at a connection portion of the plurality of channel portions CHa and CHb. As another example, the plurality of channel portions CHa and CHb may have an inclined side surface continuously connected without a bent portion. FIG. 2 illustrates that the channel insulating layer 150, the channel layer 142, and the core insulating layer 140 of the plurality of channel portions CHa and CHb extend from each other to have an integral structure. However, the embodiment is not limited thereto, and the channel insulating layer 150, the channel layer 142, and the core insulating layer 140 of the plurality of channel portions CHa and CHb may be formed separately from each other to be electrically connected to each other. In addition, a separate channel pad may be additionally provided at the connection portion of the plurality of channel portions CHa and CHb. The embodiment described above is not limited to the form of the plurality of channel portions CHa and CHb.

In the embodiment, the gate stacked structure 120 may be divided into a plurality of pieces in a plan view by a separation structure 146 extending in a direction crossing the second substrate 110 (for example, a perpendicular direction, the Z-axis direction in the drawing) to penetrate the gate stacked structure 120. In a plan view, a plurality of separation structures 146 may be provided to extend in a first direction (Y-axis direction in the drawing) and be spaced apart from each other at a predetermined interval in a second direction (X-axis direction in the drawing) crossing the first direction.

By the separation structure 146, in a plan view, the plurality of gate stacked structures 120 may extend in the first direction (Y-axis direction of the drawing) and may be spaced apart from each other at a predetermined interval in the second direction (X-axis direction of the drawing). The gate stacked structure 120 partitioned by the separation structure 146 may configure one memory cell block. However, the embodiment is not limited thereto, and the range of the memory cell block is not limited thereto.

For example, the separation structure 146 may pass through the gate stacked structure 120 to extend to the second substrate 110. As an example, the separation structure 146 has been illustrated to have an inclined side surface whose width gradually decreases toward the second substrate 110 when viewed in a cross-sectional view due to a high aspect ratio, but the embodiment is not limited thereto. The side surface of the separation structure 146 may be perpendicular to the second substrate 110, or may have a bent portion at the connection portion of the plurality of stacked structures 120a and 120b.

The separation structure 146 may be filled with various insulating materials. For example, the separation structure 146 may include an insulating material such as a silicon oxide, a silicon nitride, or a silicon oxynitride. However, the embodiment is not limited thereto, and the structure, shape, material, and the like of the separation structure 146 may be variously modified.

The connection area 104 and the second wiring portion 180 may be provided to connect the gate stacked structure 120 and the channel structure CH provided in the cell array area 102 to the circuit area 200 or an external circuit. The connection area 104 may be disposed around the cell array area 102, and at least a portion of the second wiring portion 180 may be disposed.

Here, the second wiring portion 180 may include all members electrically connecting the gate electrode 130, the channel structure CH, the horizontal conductive layers 112 and 114, and/or the second substrate 110 to the circuit area 200 or an external circuit. For example, the second wiring portion 180 may include a bit line 182, a gate contact portion 184, a source contact portion 186, a through plug 188, a contact via 180a respectively connected to them, and a connection wiring 190 connecting them.

The bit line 182 may be disposed on the cell insulating layer 132 of the gate stacked structure 120 formed in the cell array area 102. The bit line 182 may extend in a crossing direction (X-axis direction of the drawing) crossing one direction in which the gate electrode 130 extends. The bit line 182 may be electrically connected to the channel structure CH, for example, the channel pad 144, through the contact via 180a, for example, a bit line contact via.

A plurality of gate electrodes 130 may extend and be disposed in the connection area 104 in the first direction (Y-axis direction of the drawing), and the extension lengths of the plurality of gate electrodes 130 in the connection area 104 may become sequentially smaller as they move away from the second substrate 110. For example, the plurality of gate electrodes 130 may be disposed in the connection area 104 with a step shape. In this case, the plurality of gate electrodes 130 may have a step shape in one direction or in a plurality of directions. In the connection area 104, the plurality of gate contact portions 184 may be electrically connected to the plurality of gate electrodes 130 passing through the cell insulating layer 132 and extending to the connection area 104, respectively. In addition, in the connection area 104, the source contact portion 186 may pass through the cell insulating layer 132 to be electrically connected to the horizontal conductive layers 112 and 114 and/or the second substrate 110, and the through plug 188 may pass through the gate stacked structure 120 or be disposed outside the gate stacked structure 120 to be electrically connected to the first wiring portion 230 of the circuit area 200.

As a different example from the above-described example, the gate contact portion 184 may pass through the cell insulating layer 132 and the gate electrode 130 to extend to the first wiring portion 230 provided in the circuit area 200. In this case, the gate contact portion 184 may include a connection portion connected to a connection gate electrode that must be connected among the plurality of gate electrodes 130 included in the gate stacked structure 120. In addition, the gate contact portion 184 may be insulated from the remaining gate electrodes that should not be connected among the gate electrodes 130 by an insulating material.

The connection wiring 190 may be disposed in the cell array area 102 and/or the connection area 104. The bit line 182, the source contact portion 186, and/or the through plug 188 may be electrically connected to the connection wiring 190. For example, the gate contact portion 184, the source contact portion 186, and/or the through plug 188 may be connected to the connection wiring 190 through the contact via 180a. However, the embodiment is not limited thereto.

In FIG. 1, it is illustrated that the connection wiring 190 is provided as a single layer disposed on the same plane as the bit line 182 and a second insulating layer 192 is disposed in a portion other than the second wiring portion 180. However, this is only a brief illustration for convenience. Accordingly, the connection wiring 190 may include a plurality of wiring layers and contact vias for electrical connection with the bit line 182, the gate contact portion 184, the source contact portion 186, and/or the through plug 188.

In this way, the bit line 182, the gate electrode 130, the horizontal conductive layers 112 and 114, and/or the second substrate 110 connected to the channel structure CH may be electrically connected to the circuit element 220 of the circuit area 200 by the second wiring portion 180 and the first wiring portion 230.

In FIG. 1, it is illustrated that the gate contact portion 184, the source contact portion 186, and/or the through plug 188 have inclined side surfaces so that the width thereof becomes narrower as the width thereof approaches the second substrate 110 according to the aspect ratio when viewed in a cross-sectional view, and have bent portions at the boundary of the plurality of gate stacked structures 120a and 120b. However, the embodiment is not limited thereto. The gate contact portion 184, the source contact portion 186, and/or the through plug 188 may not have a bent portion at the boundary of the plurality of gate stacked structures 120a and 120b. Various other variations are possible.

Referring to FIG. 2, the semiconductor device according to the present embodiment is characterized in that a ferroelectric pattern 300 is disposed around the channel structure CH and a thickness of the ferroelectric pattern 300 in the third direction (Z direction) is thinner than that of the gate electrode 130 in the third direction (Z direction) to improve the reliability of the semiconductor device. Hereinafter, a semiconductor device according to the present embodiment will be described with reference to FIG. 2 to FIG. 5 in detail.

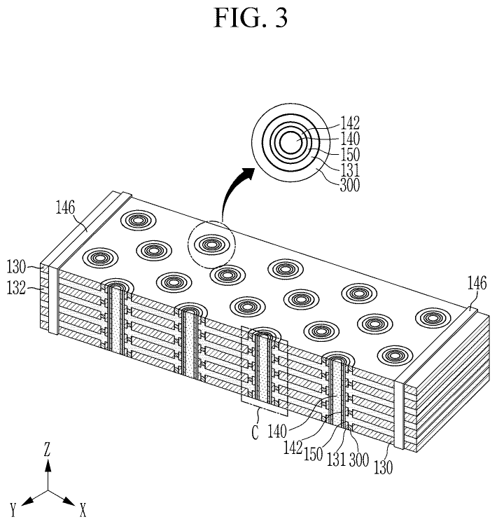

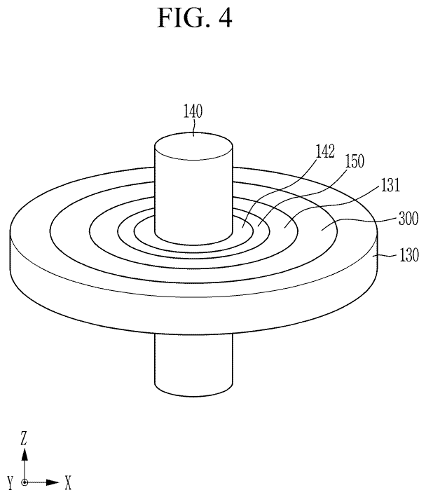

FIG. 3 illustrates an enlarged view of a portion of the cell array area 102 of the semiconductor device 10 illustrated in FIG. 1, and FIG. 4 illustrates a perspective view of the channel structure CH of FIG. 3.

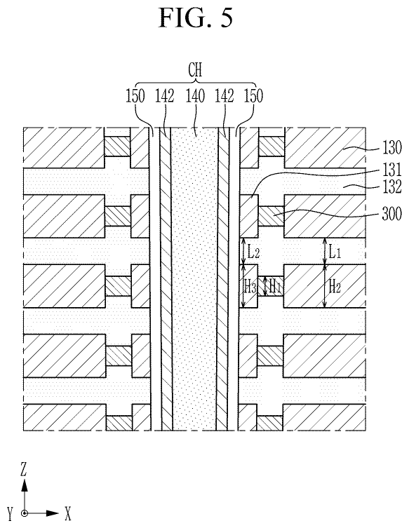

FIG. 5 illustrates a portion indicated by C in FIG. 3.

Referring to FIG. 3 and FIG. 4, the channel structure CH may include a cylindrical core insulating layer 140, a channel layer 142 having an annular shape in a plan view and surrounding the core insulating layer 140, and a channel insulating layer 150 having an annular shape in a plan view and surrounding the channel layer 142. Descriptions of the core insulating layer 140, the channel layer 142, and the channel insulating layer 150 are the same as those described above for the channel structure CH, and thus are omitted. Moreover, for the purposes of clarity and brevity, the thickness, in the Z-direction, of the channel layer 142, the channel insulating layer 150, the conductive pattern 131, the ferroelectric pattern 300, and the gate electrode 130 are not proportionally shown, and gate insulating film 132 is omitted in FIG. 4. For example, the channel layer 142 and the channel insulating layer 150 may extend along the length, in the Z-direction, of the core insulating layer 140 such that the thickness of the channel layer 142 and the thickness of the channel insulating layer 150 are the same or substantially the same as the thickness of the core insulating layer 140.

Referring to FIG. 4 and FIG. 5, a conductive pattern 131 is disposed on a side surface of the channel insulating layer 150. The conductive pattern 131 may surround at least a portion of the channel insulating layer 150. The conductive pattern 131 may be disposed between the gate electrode 130 and the channel layer 142. For example, the conductive pattern 131 may be disposed between the ferroelectric pattern 300 and the channel insulating layer 150, which will be described later.

In the embodiment, as illustrated in FIG. 4, the conductive pattern 131 may extend along the circumferential direction of the channel structure CH. For example, the conductive pattern 131 may have an annular shape in a plan view and surround at least a portion of the channel insulating layer 150. In other words, the conductive pattern 131 may extend in the circumferential direction of the channel structure CH to cover the side surface of the channel insulating layer 150.

In addition, referring to FIG. 2 and FIG. 3 together, a plurality of conductive patterns 131 may be provided so as to be spaced apart from each other at predetermined intervals along the third direction (Z direction). Each of the plurality of conductive patterns 131 disposed to be spaced apart along the third direction (Z direction) may surround at least a portion of the channel insulating layer 150. Specifically, the plurality of conductive patterns 131 may be disposed between the plurality of gate electrodes 130 and the channel insulating layer 150, and may not be disposed between the plurality of interlayer insulating layers 132 and the channel insulating layer 150. That is, the conductive pattern 131 may overlap the plurality of gate electrodes 130 in the radial direction of the channel structure CH, and may not overlap the plurality of interlayer insulating layers 132 in the radial direction of the channel structure CH.

In the embodiment, the upper surface of the conductive pattern 131 may be disposed at substantially the same level (in the Z-direction) as the upper surface of the gate electrode 130 adjacent to the conductive pattern 131. That is, along the vertical direction (e.g., the Z-direction) of a channel structure CH, the upper surface of a conductive pattern 131 and the upper surface of an adjacent gate electrode 130 may be disposed at substantially the same distance from the upper surface of the second substrate 110. In addition, along the vertical direction (e.g., the Z-direction) of the channel structure CH, the lower surface of a conductive pattern 131 and the lower surface of an adjacent gate electrode 130 may be disposed at substantially the same distance from the upper surface of the second substrate 110. For example, along the vertical direction of the channel structure CH, the upper surface of a conductive pattern 131 and the upper surface of an adjacent gate electrode 130 are disposed at the same level, and the lower surface of a conductive pattern 131 and the lower surface an adjacent gate electrode 130 are disposed at the same level. Here, the gate electrode 130 adjacent to the conductive pattern 131 may mean a gate electrode 130 overlapping the conductive pattern 131 in the radial direction of the channel structure CH among the plurality of gate electrodes 130. Accordingly, the thickness of the conductive pattern 131 in the third direction (Z direction) may be substantially the same as the thickness of the plurality of gate electrodes 130 in the third direction (Z direction).

That is, as illustrated in FIG. 5, a thickness H3 of the conductive pattern 131 in the third direction (Z direction) may be the same as a thickness H2 of the gate electrode 130 in the third direction (Z direction). However, this is only an example, and in another embodiment, the thickness H3 of the conductive pattern 131 in the third direction (Z direction) may be thicker than the thickness H2 of the gate electrode 130 in the third direction (Z direction).

As illustrated in FIG. 5, in the present embodiment, since the thickness H3 of the conductive pattern 131 in the third direction (Z direction) and the thickness H2 of the gate electrode 130 in the third direction (Z direction) are the same, a thickness L2 of the gate insulating film 132 overlapping the conductive pattern 131 in the third direction (Z direction) and a thickness L1 of the gate electrode 130 overlapping the gate electrode 130 in the third direction (Z direction) may be the same. That is, in the embodiment of FIG. 5, L1=L2 and H2=H3. However, this is an example, and in another embodiment, the thickness L2 in the third direction (Z direction) of the gate insulating film 132 overlapping the conductive pattern 131 in the third direction (Z direction) and the thickness L1 in the third direction (Z direction) of the gate electrode 130 overlapping the gate electrode 130 in the third direction (Z direction) may be different. Specifically, the thickness L2 in the third direction (Z direction) of the gate insulating film 132 overlapping the conductive pattern 131 in the third direction (Z direction) may be thinner than the thickness L1 in the third direction (Z direction) of the gate electrode 130 overlapping the gate electrode 130 in the third direction (Z direction).

In the embodiment, the conductive pattern 131 may include a conductive material. For example, the conductive pattern 131 may include a metal material such as tungsten (W), rubidium (Rb), copper (Cu), aluminum (Al), and the like. The plurality of gate electrodes 130 may include a metal material such as tungsten (W), copper (Cu), and aluminum (Al), a polycrystalline silicon, a metal nitride (for example, titanium nitride (TiN), tantalum nitride (TaN), and the like), or a combination thereof.

In the embodiment, the conductive pattern 131 may include the same material as the plurality of gate electrodes 130. For example, the conductive pattern 131 and the plurality of gate electrodes 130 may include tungsten (W). In this case, when a voltage is applied to the plurality of gate electrodes 130, an electric field may be greatly concentrated within the conductive pattern 131. Accordingly, the operating voltage characteristics for forming the residual polarization of the ferroelectric pattern 300 in contact with the conductive pattern 131 may be improved. However, the present disclosure is not limited thereto, and the conductive pattern 131 may include a material different from the plurality of gate electrodes 130. Even in this case, when a voltage is applied to the plurality of gate electrodes 130, an electric field may be concentrated within the conductive pattern 131. A detailed description thereof will be described later in the description of the ferroelectric pattern 300.

The ferroelectric pattern 300 may be disposed on the side surface of the conductive pattern 131. For example, the ferroelectric pattern 300 may be disposed on and in contact with the outer surface of the conductive pattern 131. The inner surface of the conductive pattern 131 may contact the channel insulating layer 150. The ferroelectric pattern 300 may surround the conductive pattern 131. The ferroelectric pattern 300 may be disposed between the gate electrode 130 and the channel layer 142. For example, the ferroelectric pattern 300 may be disposed between the conductive pattern 131 and the gate electrode 130. The ferroelectric pattern 300 may be in contact with the side surface (i.e., outer surface) of the conductive pattern 131 and the side surface of the gate electrode 130.

In the embodiment, as illustrated in FIG. 4, the ferroelectric pattern 300 may extend along the circumferential direction of the channel structure CH. For example, the ferroelectric pattern 300 may have an annular shape in a plan view and surround the conductive pattern 131. In other words, the ferroelectric pattern 300 may extend in the circumferential direction of the channel structure CH to surround the outer surface of the conductive pattern 131. That is, the ferroelectric pattern 300 may cover the side surface of the conductive pattern 131 along the circumferential direction of the channel structure CH.

In addition, referring to FIG. 2 and FIG. 3 together, a plurality of ferroelectric patterns 300 may be provided so as to be spaced apart from each other at predetermined intervals along the third direction (Z direction). That is, the plurality of ferroelectric patterns 300 may be disposed to be spaced apart from each other in the third direction (Z direction). Each of the plurality of ferroelectric patterns 300 disposed to be spaced apart from each other along the third direction (Z direction) may surround the conductive pattern 131. Specifically, the plurality of ferroelectric patterns 300 may be disposed between the plurality of gate electrodes 130 and the conductive pattern 131, and may not be disposed between the plurality of interlayer insulating layers 132 and the channel insulating layer 150. That is, the ferroelectric pattern 300 may overlap the plurality of gate electrodes 130 in the radial direction of the channel structure CH, and may not overlap the plurality of interlayer insulating layers 132 in the radial direction of the channel structure CH.

Referring to FIG. 5, the upper surface of a ferroelectric pattern 300 may be disposed at a level (in the Z-direction) lower than the upper surface of a conductive pattern 131 adjacent to the ferroelectric pattern 300. That is, referring to FIG. 2 and FIG. 5 together, a distance between the upper surface of a ferroelectric pattern 300 and the upper surface of the second substrate 110 may be shorter than a distance between the upper surface of an adjacent conductive pattern 131 and the upper surface of the second substrate 110. In addition, the lower surface of a ferroelectric pattern 300 may be disposed at a level higher than the lower surface of an adjacent conductive pattern 131. That is, a distance between the lower surface of the ferroelectric pattern 300 and the second substrate 110 may be longer than a distance between the lower surface of the adjacent conductive pattern 131 and the second substrate 110.

In addition, the upper surface of a ferroelectric pattern 300 may be disposed at a level lower than the upper surface of a gate electrode 130 adjacent to the ferroelectric pattern 300. That is, the distance between the upper surface of a ferroelectric pattern 300 and the second substrate 110 may be shorter than the distance between the upper surface of a gate electrode 130 adjacent to the ferroelectric pattern 300 and the second substrate 110. In addition, the lower surface of a ferroelectric pattern 300 may be disposed at a level higher than the lower surface of an adjacent conductive pattern 131. That is, the distance between the lower surface of the ferroelectric pattern 300 and the second substrate 110 may be longer than the distance between the lower surface of the gate electrode 130 adjacent to the ferroelectric pattern 300 and the second substrate 110.

As shown in FIG. 5, the thickness H1 of the ferroelectric pattern 300 in the third direction (Z direction) may be thinner than the thickness H3 of the conductive pattern 131 adjacent to the ferroelectric pattern in the third direction (Z direction). Likewise, the thickness H1 of the ferroelectric pattern 300 in the third direction (Z direction) may be thinner than the thickness H2 of the gate electrode 130 adjacent to the ferroelectric pattern in the third direction (Z direction). As will be described separately later, as the thickness H1 of the ferroelectric pattern 300 in the third direction (Z direction) is formed thinner than the thickness H3 of the conductive pattern 131 adjacent to the ferroelectric pattern in the third direction (Z direction) and the thickness H2 of the gate electrode 130 adjacent to the ferroelectric pattern in the third direction (Z direction), by reducing the capacitance of the ferroelectric pattern 300, the intensity of the electric field applied to the ferroelectric pattern 300 may be increased, and the reliability of the semiconductor device may be improved.

Specifically, the thickness H1 of the ferroelectric pattern 300 in the third direction (Z direction) may be 50% to 70% of the thickness H2 of the gate electrode 130 in the third direction (Z direction). When the thickness H1 of the ferroelectric pattern 300 in the third direction (Z direction) is less than 50% of the thickness H2 of the gate electrode 130 in the third direction (Z direction), the ferroelectric pattern 300 may not sufficiently function as a non-volatile memory layer. In addition, when the thickness H1 of the ferroelectric pattern 300 in the third direction (Z direction) exceeds 70% of the thickness H2 of the gate electrode 130 in the third direction (Z direction), the capacitance reduction effect by reducing the thickness H1 of the ferroelectric pattern 300 may not be sufficient.

As illustrated in FIG. 5, a distance between two conductive patterns 131 adjacent to each other in the third direction (Z direction) may be shorter than a distance between two ferroelectric patterns 300 adjacent to each other in the third direction (Z direction). In addition, as shown in FIG. 5, a partial area of the interlayer insulating layer 132 may overlap the conductive pattern 131 and the gate electrode 130 in the radial direction of the channel structure CH.

The ferroelectric pattern 300 may include a ferroelectric material. For example, the ferroelectric pattern 300 may include an Hf compound with ferroelectric characteristics. For example, the ferroelectric pattern 300 may include HfO₂, HfZnO, HfSiO, HfSiON, HfTaO, HfTiO, HfZrO, or a combination thereof. In addition, the ferroelectric pattern 300 may include, for example, a ferroelectric material having a perovskite structure such as PZT(PbZrₓTi₁₋ₓO₃), BaTiO₃, and PbTiO₃. The ferroelectric pattern 300 may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La). The ferroelectric pattern 300 may be made of a crystalline material. For example, the ferroelectric pattern 300 may have a crystal structure of an orthorhombic system.

In the embodiment, when the ferroelectric pattern 300 includes a ferroelectricity, the ferroelectric pattern 300 may be configured to have polarization in various states according to a voltage applied between the plurality of gate electrodes 130 and the channel layer 142. For example, when an external electric field (for example, an electric field generated by a voltage difference applied between the plurality of gate electrodes 130 and the channel layer 142) is applied to the ferroelectric pattern 300, remnant polarization may be generated within the ferroelectric pattern 300. On the other hand, even when an external electric field (for example, an electric field generated by a voltage difference applied between the plurality of gate electrodes 130 and the channel layer 142) is not applied to the ferroelectric pattern 300, the already generated remnant polarization may be kept constant.

Here, the magnitude of the residual polarization generated in the ferroelectric pattern 300 may be determined by polarization-voltage (PV) hysteresis characteristics that take into account not only the magnitude of the voltage applied between the plurality of gate electrodes 130 and the channel layer 142 but also the process through which the remnant polarization generated in the ferroelectric pattern 300 has passed. The generated remnant polarization may be stored in the ferroelectric pattern 300, and signal information may be non-volatilely stored by the stored remnant polarization. That is, the ferroelectric pattern 300 may function as a non-volatile memory layer.

In this case, according to the embodiment, when a voltage is applied to the plurality of gate electrodes 130, an electric field may be concentrated within the conductive pattern 131. In the embodiment, since the conductive pattern 131 includes a conductive material, the electric field may be distributed with a uniform density in the conductive pattern 131. Accordingly, an electric field of a uniform density may be distributed in a portion of the ferroelectric pattern 300 overlapping the conductive pattern 131 in the radial direction of the channel structure CH, and remnant polarization may be uniformly generated in the ferroelectric pattern 300. Therefore, the reliability of the semiconductor device 10 may be improved.

As in the present embodiment, the semiconductor device including the ferroelectric pattern 300 may have excellent characteristics when the capacitance of the ferroelectric pattern 300 is small and the capacitance of a portion of the channel insulating layer 150 adjacent to the ferroelectric pattern 300 is large.

However, in the case of a semiconductor device including the ferroelectric pattern 300, as shown in FIG. 4, the ferroelectric pattern 300 is disposed outside the channel insulating layer 150. Therefore, the radius of the ferroelectric pattern 300 is larger than the radius of the channel insulating layer 150, and the ferroelectric pattern 300 has a higher capacitance than the channel insulating layer 150. When the capacitance of the ferroelectric pattern 300 increases as described above, the electric field of the ferroelectric pattern 300 decreases, which is not preferable.

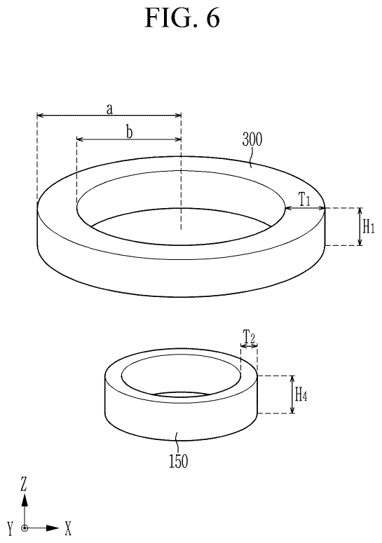

FIG. 6 illustrates the ferroelectric pattern 300 and the portion of the channel insulating layer 150 adjacent to the ferroelectric pattern 300 of FIG. 4 separately. The portion of the channel insulating layer 150 adjacent to the ferroelectric pattern 300 refers to the portion of the channel insulating layer 150 in contact with the adjacent conductive pattern 131, which is adjacent to the ferroelectric pattern 300. The thickness of the portion of the channel insulating layer 150 is the same as the thickness of the adjacent conductive pattern 131. Equation 1, Equation 2, and Equation 3 below represent equations for obtaining the capacitance of the ferroelectric pattern 300 and the channel insulating layer 150 of FIG. 6.

$$C = \frac{v \cdot {k}_{x} \cdot {ε}_{0}}{t} \qquad [ Equation 1 ]$$

$$v = A \cdot h \qquad [ Equation 2 ]$$

$$A = {π}^{2} \cdot ( {a}^{2} - {b}^{2} ) \qquad [ Equation 3 ]$$

In Equation 1, kₓ is a dielectric constant of each of the ferroelectric pattern 300 and the channel insulating layer 150, and t means a thickness T1 in the radial direction of the ferroelectric pattern 300 and a thickness T2 in the radial direction of the channel insulating layer 150 as shown in FIG. 6. In Equation 3, h represents thickness, such as the thickness H1 of the ferroelectric pattern 300 and thickness H4 of the channel insulating layer 150. As described above, the thickness of the portion of the channel insulating layer 150 is the same as the thickness of the adjacent conductive pattern 131. Accordingly, the thickness H4 is equal to the thickness H3.

Referring to FIG. 4 and FIG. 6, since the ferroelectric pattern 300 is disposed in a circular shape outside the adjacent portion of the channel insulating layer 150, a planar area (A) of the ferroelectric pattern 300 derived from Equation 3 is larger than a planar area (A) of the adjacent portion of the channel insulating layer 150. Therefore, referring to Equation 2, when the thickness H1 of the ferroelectric pattern 300 and the thickness H4 of the adjacent portion of the channel insulating layer 150 are the same, a volume (V) of the ferroelectric pattern 300 becomes larger than a volume V of the adjacent portion of the channel insulating layer (150). Therefore, referring to Equation 1, since the volume (V) of the ferroelectric pattern 300 is greater than the volume (V) of the adjacent portion of the channel insulating layer 150, the capacitance of the ferroelectric pattern 300 becomes larger than the capacitance of the adjacent portion of the channel insulating layer 150.

As the capacitance of the dielectric material increases, the electric field decreases. In the case of the semiconductor device according to the present embodiment, as the electric field applied to the ferroelectric pattern 300 increases, the switching efficiency of the device is improved, and RC delay and reliability are improved, so that it is necessary to reduce the capacitance of the ferroelectric pattern 300. In addition, since the semiconductor device according to the present embodiment has improved durability as the electric field applied to the adjacent portion of the channel insulating layer 150 becomes smaller, it is necessary to increase the capacitance of the adjacent portion of the channel insulating layer 150 and reduce the electric field, and to reduce the capacitance of the ferroelectric pattern 300 and increase the electric field.

Accordingly, in the semiconductor device according to the present embodiment, the thickness H1 of the ferroelectric pattern 300 is formed thinner than the thickness H3 of the conductive pattern 131 and the thickness H2 of the gate electrode 130 to reduce the capacitance of the ferroelectric pattern 300. Therefore, the characteristics and reliability of the semiconductor device are improved. That is, as the thickness H1 of the ferroelectric pattern 300 decreases, the volume (V) derived from Equation 2 decreases, and as the volume (V) decreases, the capacitance derived from Equation 1 decreases.

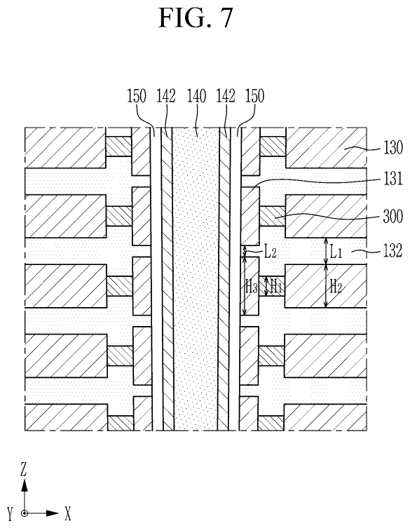

FIG. 7 illustrates another embodiment having the same cross-section as FIG. 5. Referring to FIG. 7, the semiconductor device according to the present embodiment is the same as the embodiment of FIG. 5, except that the thickness H3 of the conductive pattern 131 in the third direction (Z direction) is thicker than the thickness H2 of the gate electrode 130 in the third direction (Z direction), and the thickness L2 in the third direction (Z direction) of the gate insulating film 132 overlapping the conductive pattern 131 in the third direction (Z direction) is thinner than the thickness L1 in the third direction (Z direction) of the gate electrode 130 overlapping the gate electrode 130 in the third direction (Z direction). Detailed description of the same constituent elements will be omitted.

That is, the embodiment of FIG. 5 is different from the embodiment of FIG. 7 in that L1=L2, H2=H3 in the embodiment of FIG. 5 and H3>H2 and L1>L2 in the embodiment of FIG. 7. This configuration is derived because the deposition thickness is different depending on the surface on which the gate insulating film 132 is formed during the manufacturing process, which will be described in detail later by a separate manufacturing method.

As shown in FIG. 7, the upper surface of the conductive pattern 131 may be disposed at a level higher (in the Z-direction) than the upper surface of the gate electrode 130 adjacent to the conductive pattern 131. That is, along the vertical direction (e.g., the Z-direction) of a channel structure CH, the upper surface of a conductive pattern 131 may be disposed farther from the upper surface of the second substrate 110 than the upper surface of a gate electrode 130 adjacent to the conductive pattern 131. In addition, along the vertical direction (e.g., the Z-direction) of the channel structure CH, the lower surface of a conductive pattern 131 may be disposed at a lower level than the lower surface of a gate electrode 130 adjacent to the conductive pattern 131. That is, the lower surface of the conductive pattern 131 may be disposed closer to the upper surface of the second substrate 110 than the lower surface of the gate electrode 130 adjacent to the conductive pattern 131.

Even in FIG. 7, similarly to FIG. 5, the thickness H1 of the ferroelectric pattern 300 in the third direction (Z direction) may be thinner than the thickness H3 of the conductive pattern 131 adjacent to the ferroelectric pattern in the third direction (Z direction). Likewise, the thickness H1 of the ferroelectric pattern 300 in the third direction (Z direction) may be thinner than the thickness H2 of the gate electrode 130 adjacent to the ferroelectric pattern in the third direction (Z direction). As described above, the thickness H1 of the ferroelectric pattern 300 in the third direction (Z direction) may be 50% to 70% of the thickness H2 of the gate electrode 130 in the third direction (Z direction).

That is, the upper surface of the ferroelectric pattern 300 may be disposed at a level lower than the upper surface of the conductive pattern 131 adjacent to the ferroelectric pattern 300. That is, a distance between the upper surface of the ferroelectric pattern 300 and the second substrate 110 may be shorter than a distance between the upper surface of the conductive pattern 131 and the second substrate 110. In addition, the lower surface of the ferroelectric pattern 300 may be disposed at a level higher than the lower surface of the conductive pattern 131. That is, a distance between the lower surface of the ferroelectric pattern 300 and the second substrate 110 may be longer than a distance between the lower surface of the conductive pattern 131 and the second substrate 110.

In addition, the upper surface of the ferroelectric pattern 300 may be disposed at a level lower than the upper surface of the gate electrode 130 adjacent to the ferroelectric pattern 300. That is, the distance between the upper surface of the ferroelectric pattern 300 and the second substrate 110 may be shorter than the distance between the upper surface of the gate electrode 130 adjacent to the ferroelectric pattern 300 and the second substrate 110. In addition, the lower surface of the ferroelectric pattern 300 may be disposed at a level higher than the lower surface of the conductive pattern 131. That is, the distance between the lower surface of the ferroelectric pattern 300 and the second substrate 110 may be longer than the distance between the lower surface of the gate electrode 130 adjacent to the ferroelectric pattern 300 and the second substrate 110. That is, in FIG. 7, H3>H2>H1.

In the semiconductor device according to the present embodiment, since the thickness H3 of the conductive pattern 131 adjacent to the ferroelectric pattern in the third direction (Z direction) is greater than the thickness H2 of the gate electrode 130 adjacent to the ferroelectric pattern in the third direction (Z direction), the capacitance of the channel insulating layer 150 may be greater than that of the embodiment of FIG. 5, and the electric field applied to the channel insulating layer 150 is reduced, thereby improving endurance of the semiconductor device.

In addition, as illustrated in FIG. 7, the thickness of the gate insulating film 132 may be different for each position. That is, the thickness L2 in the third direction (Z direction) of the gate insulating film 132 overlapping the conductive pattern 131 in the third direction (Z direction) may be thinner than the thickness L1 in the third direction (Z direction) of the gate insulating film 132 overlapping the gate electrode 130 in the third direction (Z direction). Referring to FIG. 7, the upper surface of the gate insulating film 132 overlapping the conductive pattern 131 in the third direction (Z direction) may be disposed at a level lower than the upper surface of the gate insulating film 132 overlapping the gate electrode 130 in the third direction (Z direction). That is, the upper surface of the gate insulating film 132 overlapping the conductive pattern 131 in the third direction (Z direction) may be disposed closer to the upper surface of the second substrate 110 than the upper surface of the gate insulating film 132 overlapping the gate electrode 130 in the third direction (Z direction). In addition, the lower surface of the gate insulating film 132 overlapping the conductive pattern 131 in the third direction (Z direction) may be disposed at a level higher than the lower surface of the gate insulating film 132 overlapping the gate electrode 130 in the third direction (Z direction). That is, the lower surface of the gate insulating film 132 overlapping the conductive pattern 131 in the third direction (Z direction) may be disposed farther from the upper surface of the second substrate 110 than the lower surface of the gate insulating film 132 overlapping the gate electrode 130 in the third direction (Z direction).

In the embodiment of FIG. 5 and FIG. 7, the upper or lower surface of the ferroelectric pattern 300 is illustrated as being parallel to the upper surface of the second substrate 110, but in some embodiments, the upper or lower surface of the ferroelectric pattern 300 may have a curved surface. This will be described separately later, but the shape of the upper and lower surfaces of the ferroelectric pattern 300 may be dependent on an etching process for forming the ferroelectrics pattern 300.

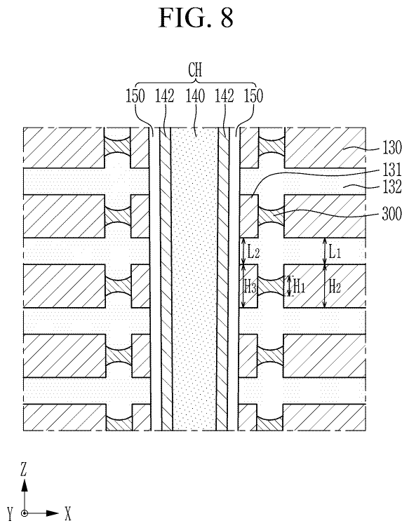

FIG. 8 illustrates another embodiment having the same cross-section as FIG. 5. Referring to FIG. 8, the semiconductor device according to the present embodiment is the same as the embodiment of FIG. 5 except that the upper and lower surfaces of the ferroelectric pattern 300 have concave curved surfaces. Detailed description of the same constituent elements will be omitted. That is, as shown in FIG. 8, the upper surface of the ferroelectric pattern 300 may have a concave curved surface with respect to the center of the ferroelectric pattern 300, and the lower surface of the ferroelectric pattern 300 may also have a concave curved surface with respect to the center of the ferroelectric pattern 300.

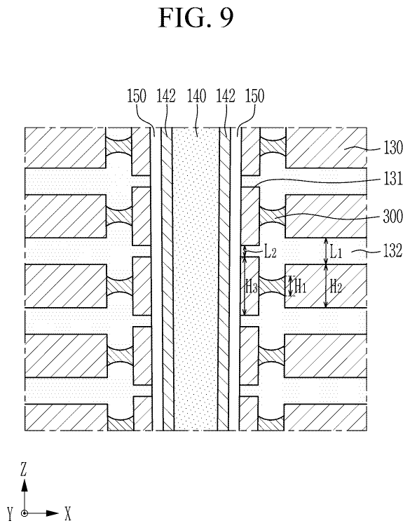

FIG. 9 illustrates another embodiment having the same cross-section as FIG. 7. Referring to FIG. 9, the semiconductor device according to the present embodiment is the same as the embodiment of FIG. 7 except that the upper and lower surfaces of the ferroelectric pattern 300 have concave curved surfaces. Detailed description of the same constituent elements will be omitted. That is, as shown in FIG. 9, the upper surface of the ferroelectric pattern 300 may have a concave curved surface with respect to the center of the ferroelectric pattern 300, and the lower surface of the ferroelectric pattern 300 may also have a concave curved surface with respect to the center of the ferroelectric pattern 300.

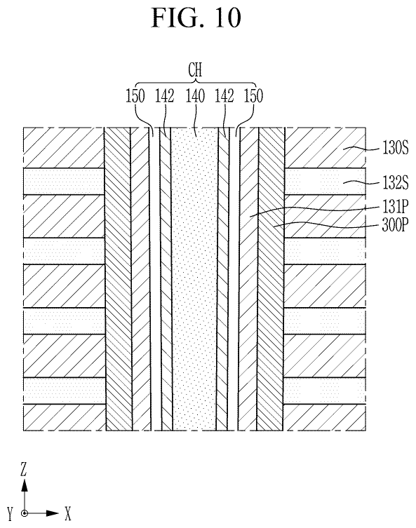

Hereinafter, a method of manufacturing a semiconductor device according to the present embodiment will be described with reference to the drawings. FIG. 10 to FIG. 18 illustrate a manufacturing method of a semiconductor device according to an embodiment. FIG. 10 to FIG. 18 illustrate a method of manufacturing the semiconductor device according to the embodiment of FIG. 5, and illustrate the same cross-sectional view as that of FIG. 5. FIG. 10 to FIG. 18 are drawn focusing on the formation process of the conductive pattern 131 and the ferroelectric pattern 300 around the channel structure CH.

Referring to FIG. 10, a plurality of sacrificial insulating layers 130S and a plurality of gate sacrificial insulating layers 132S are alternately stacked. The plurality of sacrificial insulating layers 130S may include a silicon oxide, a silicon nitride, a silicon oxynitride, a low dielectric constant material, and the like. The plurality of sacrificial insulating layers 130S may include a different material from the plurality of gate sacrificial insulating layers 132S. The plurality of sacrificial insulating layers 130S may include a material having an etch selectivity with respect to the plurality of gate sacrificial insulating layers 132S. For example, the plurality of sacrificial insulating layers 130S may include at least one of silicon, a silicon oxide, a silicon carbide, and a silicon nitride, but may be made of a different material from the plurality of gate sacrificial insulating layers 132S. For example, the plurality of gate sacrificial insulating layers 132S may include a silicon oxide, and the plurality of sacrificial insulating layers 130S may include a silicon nitride. The plurality of sacrificial insulating layers 130S may be layers that are replaced with the gate electrode (130 in FIG. 1) in a subsequent process. That is, the plurality of sacrificial insulating layers 130S may be formed to correspond to an area in which the gate electrode (130 in FIG. 1) is to be formed.

As shown in FIG. 10, a channel structure CH, the conductive electrode layer 131P, and a ferroelectric layer 300P may be formed by patterning a stacked structure of the plurality of sacrificial insulating layers 130S and the plurality of gate sacrificial insulating layers 132S. A description of the channel structure CH formed in the present step is the same as described above, and thus will be omitted. The conductive electrode layer 131P is formed around the channel structure CH. The conductive electrode layer 131P may have an annular shape in a plan view to surround the channel structure CH. In FIG. 10, the conductive electrode layer 131P may extend in the third direction (Z direction) and may be continuously disposed. The ferroelectric layer 300P is formed around the conductive electrode layer 131P. The ferroelectric layer 300P may have an annular shape in a plan view and surround the conductive electrode layer 131P. The ferroelectric layer 300P may extend in the third direction (Z direction) and may be continuously disposed. The ferroelectric layer 300P may include a ferroelectric material. For example, the ferroelectric layer 300P may include an Hf compound with ferroelectric characteristics. For example, the ferroelectric layer 300P may include HfO2, HfZnO, HfSiO, HfSiON, HfTaO, HfTiO, HfZrO, or a combination thereof. In addition, the ferroelectric layer 300P may include, for example, a ferroelectric material having a perovskite structure such as PZT(PbZrₓTi₁₋ₓO₃), BaTiO₃, and PbTiO₃. The ferroelectric layer 300P may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La).

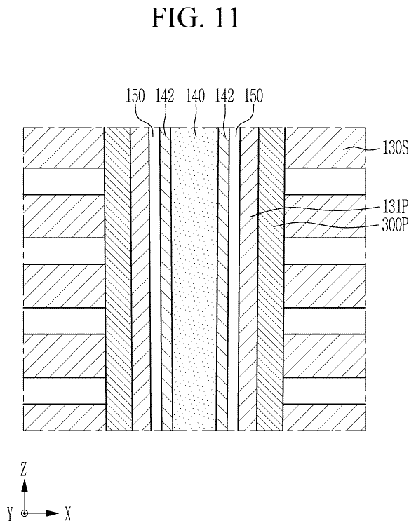

Next, referring to FIG. 11, the plurality of gate sacrificial insulating layers 132S are removed. As described above, since the plurality of gate sacrificial insulating layers 132S include a material having an etch selectivity with respect to the plurality of sacrificial insulating layers 130S, only the plurality of gate sacrificial insulating layers 132S may be removed. In the present step, a portion of the side surface of the ferroelectric layer 300P may be exposed as illustrated in FIG. 11.

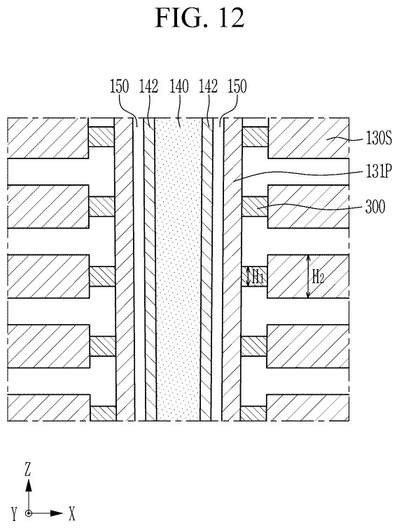

Next, referring to FIG. 12, the ferroelectric pattern 300 is formed by etching the ferroelectric layer 300P. As illustrated in FIG. 9, the ferroelectric layer 300P may be removed through the space in which the gate sacrificial insulating layer 132S is removed, thereby forming the ferroelectric pattern 300. In this case, etching may be performed until the thickness H1 of the ferroelectric pattern 300 becomes thinner than the thickness H2 of the plurality of sacrificial insulating layers 130S. Specifically, the thickness H1 of the ferroelectric pattern 300 in the third direction (Z direction) may be 50% to 70% of the thickness H2 of the sacrificial insulating layer 130S in the third direction (Z direction). FIG. 12 illustrates a configuration in which the upper and lower surfaces of the ferroelectric pattern 300 are flat, but in some embodiments, the upper and lower surfaces of the ferroelectric pattern 300 may include curved surfaces. For example, as shown in FIG. 8, the upper surface of the ferroelectric pattern 300 may have a concave curved surface with respect to the center of the ferroelectric pattern 300, and the lower surface of the ferroelectric pattern 300 may also have a concave curved surface with respect to the center of the ferroelectric pattern 300.

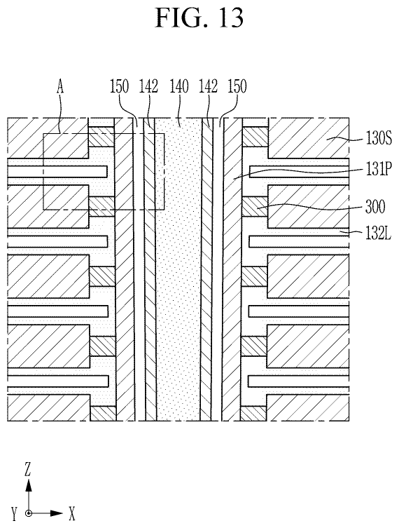

Next, referring to FIG. 13, a first gate insulating layer 132L is formed in an area from which the plurality of gate sacrificial insulating layers 132S are removed. The first gate insulating layer 132L may include a silicon oxide, a silicon nitride, a silicon oxynitride, a low dielectric constant material having a smaller dielectric constant than the silicon oxide, or a combination thereof. Referring to FIG. 13, the first gate insulating layer 132L may be formed on the surfaces of the sacrificial insulating layer 130S, the ferroelectric pattern 300, and the conductive electrode layer 131P.

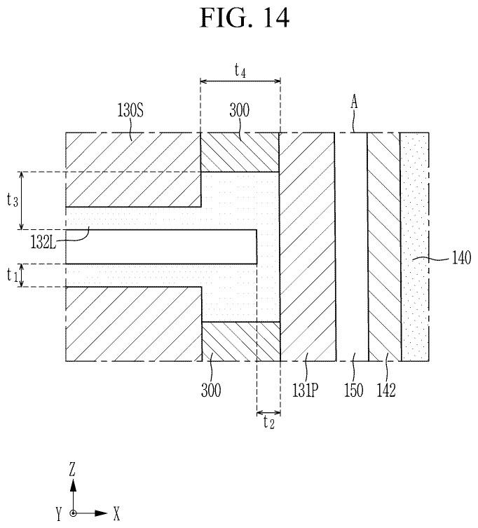

FIG. 14 illustrates an enlarged view of a portion indicated by “A” in FIG. 13. Referring to FIG. 14, a thickness T1 of the first gate insulating layer 132L formed on the sacrificial insulating layer 130S in the third direction (Z direction) may be the same as a thickness T2 of the first gate insulating layer 132L formed on the side surface of the conductive electrode layer 131P in the second direction (X direction). That is, the first gate insulating layer 132L may be formed to have a uniform thickness on surfaces of the sacrificial insulating layer 130S and the conductive electrode layer 131P. A thickness T3 in the third direction (Z direction) of the first gate insulating layer 132L overlapping the ferroelectric pattern 300 in the third direction (Z direction) may be greater than the thickness T1 of the first gate insulating layer 132L formed on the sacrificial insulating layer 130S in the third direction (Z direction). For example, the thickness T3 in the third direction (Z direction) of the first gate insulating layer 132L overlapping the ferroelectric pattern 300 in the third direction (Z direction) may be twice the thickness Ti of the first gate insulating layer 132L formed on the sacrificial insulating layer 130S in the third direction (Z direction). In addition, a width T4 in the second direction (X direction) of the first gate insulating layer 132L overlapping the ferroelectric pattern 300 in the third direction (Z direction) may be thicker than, and for example twice, the thickness T2 of the first gate insulating layer 132L formed on the side surface of the conductive electrode layer 131P in the second direction (X direction). However, these numeral values are only examples, and the present disclosure is not limited thereto.

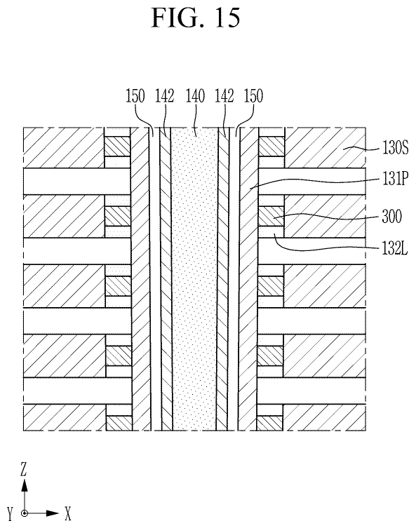

Next, referring to FIG. 15, the first gate insulating layer 132L is etched. As shown in FIG. 15, only the first gate insulating layer 132L filling the step between the ferroelectric pattern 300 and the sacrificial insulating layer 130S remains, and the remaining first gate insulating layer 132L may be etched. Therefore, as illustrated in FIG. 15, the upper surface of the first gate insulating layer 132L may be disposed at the same level as the upper surface of the sacrificial insulating layer 130S. In addition, the lower surface of the first gate insulating layer 132L may be disposed at the same level as the lower surface of the sacrificial insulating layer 130S. In the present step, the side surface of the conductive electrode layer 131P may be exposed through etching.

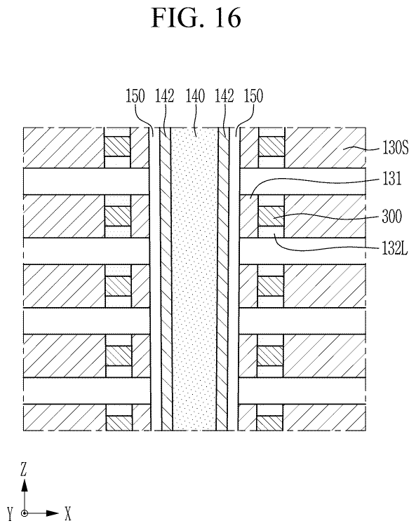

Next, referring to FIG. 16, the conductive pattern 131 is formed by etching the conductive electrode layer 131P. In the previous step, the side surface of the conductive electrode layer 131P is exposed, and the exposed conductive electrode layer 131P may be removed to form the conductive pattern 131. A plurality of conductive patterns 131 may be disposed to be spaced apart from each other in the third direction (Z direction) by etching in the present step.

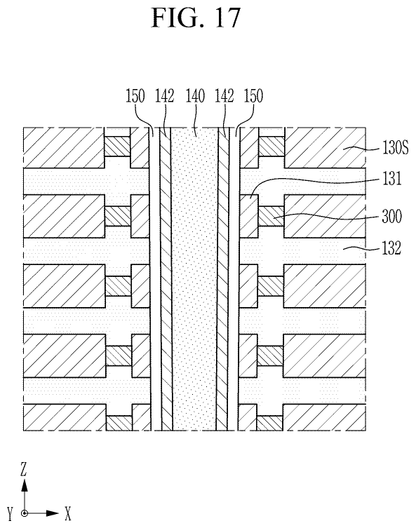

Next, referring to FIG. 17, the gate insulating layer 132 is formed in the space between the sacrificial insulating layers 130S. In this case, the gate insulating layer 132 may include the same material as the first gate insulating layer 132L formed in the previous step, and may be connected as one to the first gate insulating layer 132L formed in the previous step to configure the gate insulating layer 132.

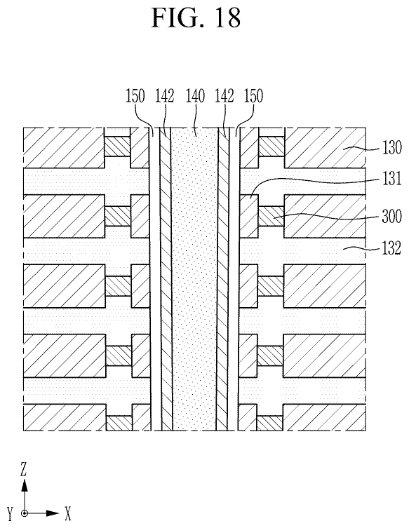

Next, referring to FIG. 18, the plurality of sacrificial insulating layers 130S are removed, and the plurality of gate electrodes 130 are formed in the space in which the plurality of sacrificial insulating layers 130S are removed. For example, after removing the plurality of sacrificial insulating layers 130S using an etching process, metal materials such as tungsten (W), copper (Cu), aluminum (Al), and the like may be deposited to form the plurality of gate electrodes 130. Referring to FIG. 18 and FIG. 2 together, the plurality of gate electrodes 130 may include a lower gate electrode 130L, a memory cell gate electrode 130M, and an upper gate electrode 130U sequentially disposed on the second substrate 110. The lower gate electrode 130L may be used as a gate electrode of a ground selection transistor, the memory cell gate electrode 130M may configure a memory cell, and the upper gate electrode 130U may be used as a gate electrode of a string selection transistor.

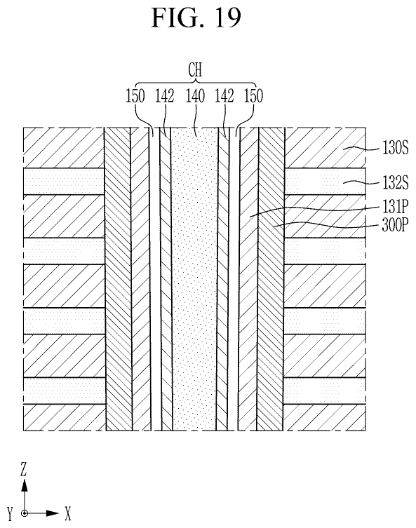

Hereinafter, a method of manufacturing a semiconductor device according to another embodiment will be described with reference to FIG. 19 to FIG. 27. FIG. 19 to FIG. 27 illustrate a method of manufacturing the semiconductor device according to the embodiment of FIG. 7, and illustrate the same cross-sectional view as that of FIG. 7. FIG. 19 to FIG. 27 are drawn focusing on the formation process of the conductive pattern 131 and the ferroelectric pattern 300 around the channel structure CH.

Referring to FIG. 19, a plurality of sacrificial insulating layers 130S and a plurality of gate sacrificial insulating layers 132S are alternately stacked. The plurality of sacrificial insulating layers 130S may include a silicon oxide, a silicon nitride, a silicon oxynitride, a low dielectric constant material, and the like. The plurality of sacrificial insulating layers 130S may include a different material from the plurality of gate sacrificial insulating layers 132S. The plurality of sacrificial insulating layers 130S may include a material having an etch selectivity with respect to the plurality of gate sacrificial insulating layers 132S. For example, the plurality of sacrificial insulating layers 130S may include at least one of silicon, a silicon oxide, a silicon carbide, and a silicon nitride, but may be made of a different material from the plurality of gate sacrificial insulating layers 132S. For example, the plurality of gate sacrificial insulating layers 132S may include a silicon oxide, and the plurality of sacrificial insulating layers 130S may include a silicon nitride. The plurality of sacrificial insulating layers 130S may be layers that are replaced with the gate electrode 130 of FIG. 1 in a subsequent process. That is, the plurality of sacrificial insulating layers 130S may be formed to correspond to an area in which the gate electrode (130 in FIG. 1) is to be formed.

As shown in FIG. 19, a channel structure CH, the conductive electrode layer 131P, and a ferroelectric layer 300P may be formed by patterning a stacked structure of the plurality of sacrificial insulating layers 130S and the plurality of gate sacrificial insulating layers 132S. A description of the channel structure CH formed in the present step is the same as described above, and thus will be omitted. The conductive electrode layer 131P is formed around the channel structure CH. The conductive electrode layer 131P may have an annular shape in a plan view to surround the channel structure CH. In FIG. 19, the conductive electrode layer 131P may extend in the third direction (Z direction) and may be continuously disposed. The ferroelectric layer 300P is formed around the conductive electrode layer 131P. The ferroelectric layer 300P may have an annular shape in a plan view and surround the conductive electrode layer 131P. The ferroelectric layer 300P may extend in the third direction (Z direction) and may be continuously disposed. The ferroelectric layer 300P may include a ferroelectric material. For example, the ferroelectric layer 300P may include an Hf compound with ferroelectric characteristics. For example, the ferroelectric layer 300P may include HfO₂, HfZnO, HfSiO, HfSiON, HfTaO, HfTiO, HfZrO, or a combination thereof. In addition, the ferroelectric layer 300P may include, for example, a ferroelectric material having a perovskite structure such as PZT(PbZrₓTi₁₋ₓO₃), BaTiO₃, PbTiO₃. The ferroelectric layer 300P may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La).

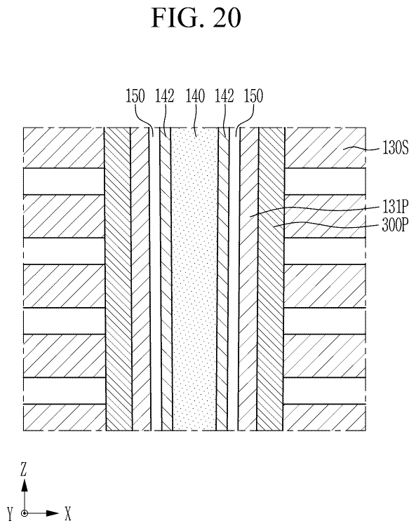

Next, referring to FIG. 20, the plurality of gate sacrificial insulating layers 132S are removed. As described above, since the plurality of gate sacrificial insulating layers 132S include a material having an etch selectivity with respect to the plurality of sacrificial insulating layers 130S, only the plurality of gate sacrificial insulating layers 132S may be removed. In the present step, a portion of the side surface of the ferroelectric layer 300P may be exposed as illustrated in FIG. 20.

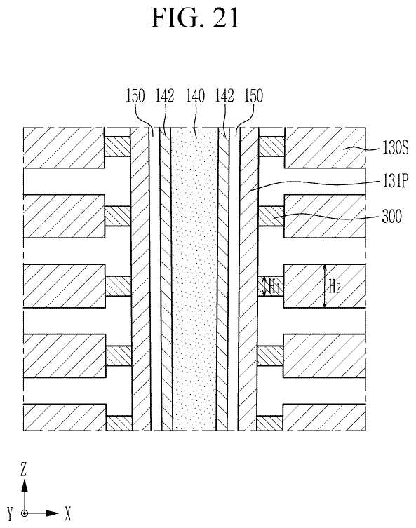

Next, referring to FIG. 21, the ferroelectric pattern 300 is formed by etching the ferroelectric layer 300P. As illustrated in FIG. 21, the ferroelectric layer 300P may be removed through the space in which the gate sacrificial insulating layer 132S is removed, thereby forming the ferroelectric pattern 300. In this case, etching may be performed until the thickness H1 of the ferroelectric pattern 300 becomes thinner than the thickness H2 of the plurality of sacrificial insulating layers 130S. Specifically, the thickness H1 of the ferroelectric pattern 300 in the third direction (Z direction) may be 50% to 70% of the thickness H2 of the sacrificial insulating layer 130S in the third direction (Z direction). FIG. 21 illustrates a configuration in which the upper and lower surfaces of the ferroelectric pattern 300 are flat, but in some embodiments, the upper and lower surfaces of the ferroelectric pattern 300 may include curved surfaces. For example, as shown in FIG. 9, the upper surface of the ferroelectric pattern 300 may have a concave curved surface with respect to the center of the ferroelectric pattern 300, and the lower surface of the ferroelectric pattern 300 may also have a concave curved surface with respect to the center of the ferroelectric pattern 300.

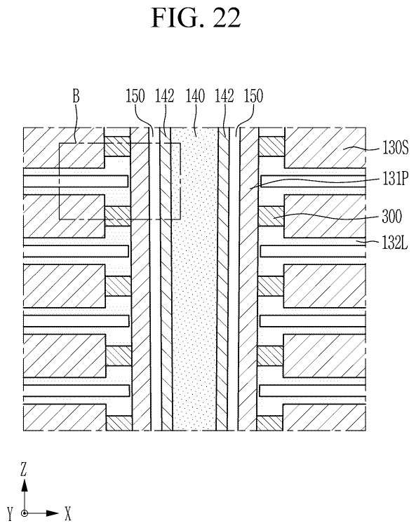

Next, referring to FIG. 22, a first gate insulating layer 132L is formed in an area from which the plurality of gate sacrificial insulating layers 132S are removed. The first gate insulating layer 132L may include a silicon oxide, a silicon nitride, a silicon oxynitride, a low dielectric constant material having a smaller dielectric constant than the silicon oxide, or a combination thereof. As shown in FIG. 22, the first gate insulating layer 132L may be formed on the surfaces of the sacrificial insulating layer 130S, the ferroelectric pattern 300, and the conductive electrode layer 131P.

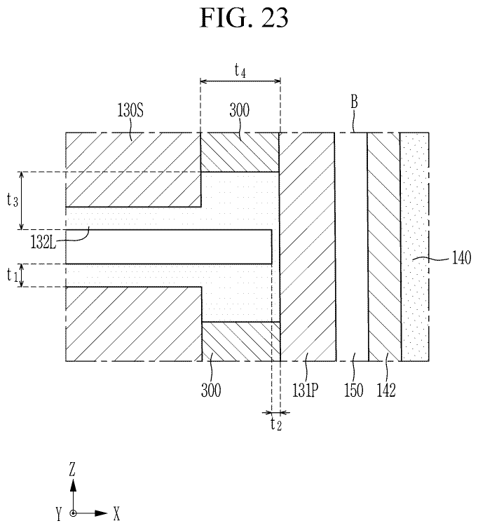

FIG. 23 illustrates an enlarged view of a portion indicated by “B” in FIG. 22. Referring to FIG. 23, a thickness T1 of the first gate insulating layer 132L formed on the sacrificial insulating layer 130S in the third direction (Z direction) may be thicker than a thickness T2 of the first gate insulating layer 132L formed on the side surface of third color filters conductive electrode layer 131P in the second direction (X direction). This is because the deposition thickness of the first gate insulating layer 132L varies depending on the surface on which the first gate insulating layer 132L is formed. That is, when the first gate insulating layer 132L is formed on the conductive electrode layer 131P, which is a metal layer, and when the first gate insulating layer 132L is formed on the sacrificial insulating layer 130S, which is an insulating layer, the deposition thickness thereof may vary. The first gate insulating layer 132L may be better formed on the sacrificial insulating layer 130S, which is the same insulating layer, but may be relatively less formed on the conductive electrode layer 131P, which is the metal layer. That is, the first gate insulating layer 132L may be formed to have a thicker thickness on the sacrificial insulating layer 130S, and may be formed to have a thinner thickness on the surface of the conductive electrode layer 131P.

Referring to FIG. 23, the thickness T3 in the third direction (Z direction) of the first gate insulating layer 132L overlapping the ferroelectric pattern 300 in the third direction (Z direction) may be greater than the thickness T1 of the first gate insulating layer 132L formed on the sacrificial insulating layer 130S in the third direction (Z direction). For example, the thickness T3 in the third direction (Z direction) of the first gate insulating layer 132L overlapping the ferroelectric pattern 300 in the third direction (Z direction) may be twice the thickness T1 of the first gate insulating layer 132L formed on the sacrificial insulating layer 130S in the third direction (Z direction). In addition, the width T4 in the second direction (X direction) of the first gate insulating layer 132L overlapping the ferroelectric pattern 300 in the third direction (Z direction) may be thicker than, and for example twice, the thickness T1 of the first gate insulating layer 132L formed on the sacrificial insulating layer 130S in the third direction (Z direction). However, these numeral values are only examples, and the present disclosure is not limited thereto.

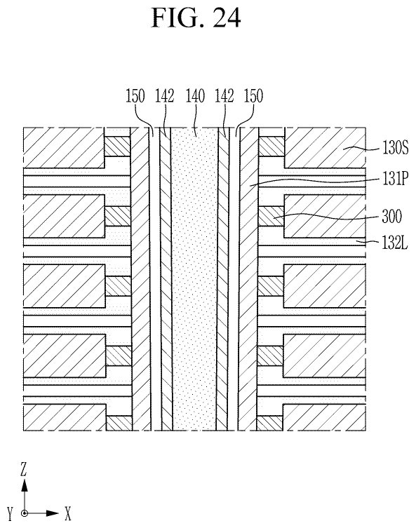

Next, referring to FIG. 24, the first gate insulating layer 132L is etched. Previously, in FIG. 22 and FIG. 23, since the thickness T1 of the first gate insulating layer 132L formed on the sacrificial insulating layer 130S is thicker than the thickness T2 of the first gate insulating layer 132L formed on the side surface of the conductive electrode layer 131P, while the first gate insulating layer 132L formed on the side surface of the conductive electrode layer 131P is removed, the first gate insulating layer 132L formed on the sacrificial insulating layer 130S may remain without being completely removed. That is, as illustrated in FIG. 24, in the present step, the first gate insulating layer 132L formed on the side surface of the conductive electrode layer 131P is removed to expose the side surface of the conductive electrode layer 131P, but the sacrificial insulating layer 130S may be covered with the first gate insulating layer 132L and may not be exposed.

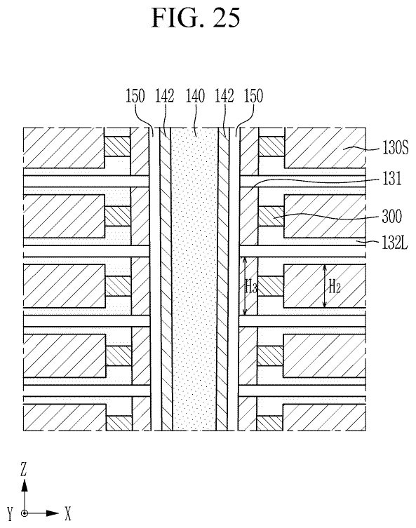

Next, referring to FIG. 25, the conductive pattern 131 is formed by etching the conductive electrode layer 131P. In the previous step, the side surface of the conductive electrode layer 131P is exposed, and the exposed area may be removed to form the conductive pattern 131. A plurality of conductive patterns 131 may be disposed to be spaced apart from each other in the third direction (Z direction) by etching in the present step. As shown in FIG. 25, the thickness H3 of the conductive pattern 131 in the third direction (Z direction) may be greater than the thickness H2 of the sacrificial insulating layer 130S in the third direction (Z direction).

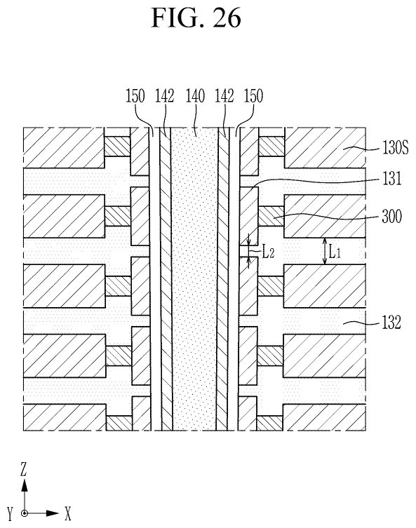

Next, referring to FIG. 26, the gate insulating layer 132 is formed in the space between the sacrificial insulating layers 130S. In this case, the gate insulating layer 132 may include the same material as the first gate insulating layer 132L formed in the previous step, and may be connected as one to the first gate insulating layer 132L formed in the previous step to configure the gate insulating layer 132. In this case, as shown in FIG. 26, the thickness L2 in the third direction (Z direction) of the gate insulating film 132 overlapping the conductive pattern 131 in the third direction (Z direction) may be thinner than the thickness L1 in the third direction (Z direction) of the gate insulating film 132 overlapping the sacrificial insulating layer 130S in the third direction (Z direction). This is because when the first gate insulating layer 132L overlapping the conductive pattern 131 in the third direction (Z direction) is removed in the previous step, the first gate insulating layer 132L overlapping the sacrificial insulating layer 130S in the third direction (Z direction) is not completely removed and partially remains.

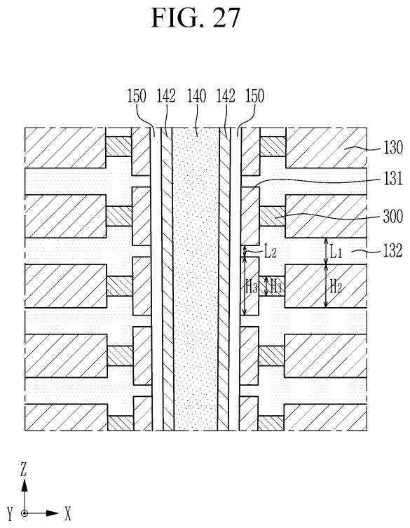

Next, referring to FIG. 27, the plurality of sacrificial insulating layers 130S are removed, and the plurality of gate electrodes 130 may be formed in the space in which the plurality of sacrificial insulating layers 130S are removed. For example, after removing the plurality of sacrificial insulating layers 130S using an etching process, metal materials such as tungsten (W), copper (Cu), aluminum (Al), and the like may be deposited to form the plurality of gate electrodes 130.

As shown in FIG. 27, in the semiconductor device manufactured according to the present manufacturing method, the thickness H3 of the conductive pattern 131 in the third direction (Z direction) may be thicker than the thickness H2 of the gate electrode 130 in the third direction (Z direction), and the thickness L2 in the third direction (Z direction) of the gate insulating film 132 overlapping the conductive pattern 131 in the third direction (Z direction) may be thinner than the thickness L1 in the third direction (Z direction) of the gate electrode 130 overlapping the gate electrode 130 in the third direction (Z direction). This is because, as described above, the thickness at which the first gate insulating layer 132L is deposited varies for each position in the deposition and etching process of the first gate insulating layer 132L.

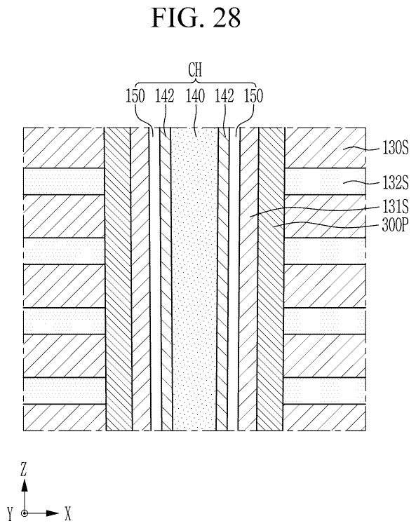

Hereinafter, a method of manufacturing a semiconductor device according to another embodiment will be described with reference to FIG. 28 to FIG. 37. FIG. 28 to FIG. 37 illustrate a method of manufacturing the semiconductor device according to the embodiment of FIG. 5, and illustrate the same cross-sectional view as that of FIG. 5. FIG. 28 to FIG. 37 are drawn focusing on the formation process of the conductive pattern 131 and the ferroelectric pattern 300 around the channel structure CH.

Referring to FIG. 28, a plurality of sacrificial insulating layers 130S and a plurality of gate sacrificial insulating layers 132S are alternately stacked. The plurality of sacrificial insulating layers 130S may include a silicon oxide, a silicon nitride, a silicon oxynitride, a low dielectric constant material, and the like. The plurality of sacrificial insulating layers 130S may include a different material from the plurality of gate sacrificial insulating layers 132S. The plurality of sacrificial insulating layers 130S may include a material having an etch selectivity with respect to the plurality of gate sacrificial insulating layers 132S. For example, the plurality of sacrificial insulating layers 130S may include at least one of silicon, a silicon oxide, a silicon carbide, and a silicon nitride, but may be made of a different material from the plurality of gate sacrificial insulating layers 132S. For example, the plurality of gate sacrificial insulating layers 132S may include a silicon oxide, and the plurality of sacrificial insulating layers 130S may include a silicon nitride. The plurality of sacrificial insulating layers 130S may be layers that are replaced with the gate electrode 130 of FIG. 1 in a subsequent process. That is, the plurality of sacrificial insulating layers 130S may be formed to correspond to an area in which the gate electrode (130 in FIG. 1) is to be formed.

As shown in FIG. 28, a channel structure CH, a sacrificial electrode layer 131S, and a ferroelectric layer 300P may be formed by patterning a stacked structure of the plurality of sacrificial insulating layers 130S and the plurality of gate sacrificial insulating layers 132S. A description of the channel structure CH formed in the present step is the same as described above, and thus will be omitted.

The manufacturing method according to the present embodiment is different from the manufacturing method of FIG. 10 to FIG. 18 described above in that the conductive electrode layer 131P is not formed, and the sacrificial electrode layer 131S is first formed. The sacrificial electrode layer 131S may include a material having an etch selectivity with respect to the plurality of sacrificial insulating layers 130S. For example, the sacrificial electrode layer 131S includes at least one of polysilicon, silicon, a silicon oxide, a silicon carbide, and a silicon nitride, and may be made of a material different from that of the sacrificial insulating layer 130S.

The sacrificial electrode layer 131S may have an annular shape in a plan view to surround the channel structure CH. In FIG. 28, the sacrificial electrode layer 131S may extend in the third direction (Z direction) and may be continuously disposed. The ferroelectric layer 300P is formed around the sacrificial electrode layer 131S. The ferroelectric layer 300P may have an annular shape in a plan view and surround the sacrificial electrode layer 131S. The ferroelectric layer 300P may extend in the third direction (Z direction) and may be continuously disposed. The ferroelectric layer 300P may include a ferroelectric material. For example, the ferroelectric layer 300P may include an Hf compound with ferroelectric characteristics. For example, the ferroelectric layer 300P may include HfO₂, HfZnO, HfSiO, HfSiON, HfTaO, HfTiO, HfZrO, or a combination thereof. In addition, the ferroelectric layer 300P may include, for example, a ferroelectric material having a perovskite structure such as PZT(PbZrₓTi₁₋ₓO₃), BaTiO₃, PbTiO₃. The ferroelectric layer 300P may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La).

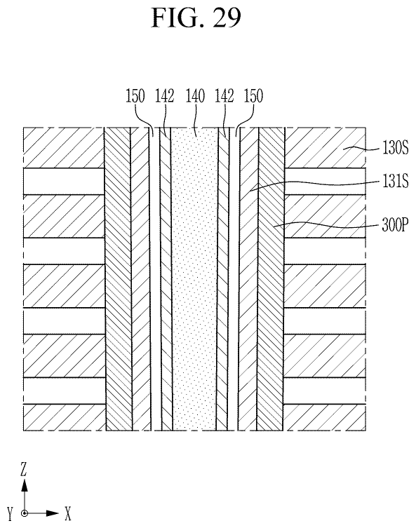

Next, referring to FIG. 29, the plurality of gate sacrificial insulating layers 132S are removed. As described above, since the plurality of gate sacrificial insulating layers 132S include a material having an etch selectivity with respect to the plurality of sacrificial insulating layers 130S, only the plurality of gate sacrificial insulating layers 132S may be removed. In the present step, a portion of the side surface of the ferroelectric layer 300P may be exposed as illustrated in FIG. 29.

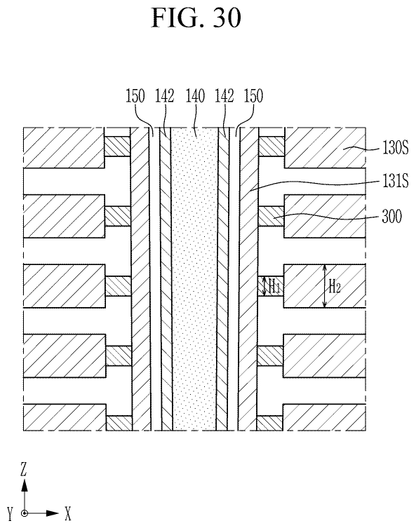

Next, referring to FIG. 30, the ferroelectric pattern 300 is formed by etching the ferroelectric layer 300P. As illustrated in FIG. 30, the ferroelectric layer 300P may be removed through the space in which the gate sacrificial insulating layer 132S is removed, thereby forming the ferroelectric pattern 300. In this case, the etching may be performed until the thickness H1 of the ferroelectric pattern 300 in the third direction (Z direction) becomes thinner than the thickness H2 of the plurality of sacrificial insulating layers 130S in the third direction (Z direction). Specifically, the thickness H1 of the ferroelectric pattern 300 in the third direction (Z direction) may be 50% to 70% of the thickness H2 of the sacrificial insulating layer 130S in the third direction (Z direction). FIG. 30 illustrates a configuration in which the upper and lower surfaces of the ferroelectric pattern 300 are flat, but in some embodiments, the upper and lower surfaces of the ferroelectric pattern 300 may include curved surfaces. For example, as shown in FIG. 8, the upper surface of the ferroelectric pattern 300 may have a concave curved surface with respect to the center of the ferroelectric pattern 300, and the lower surface of the ferroelectric pattern 300 may also have a concave curved surface with respect to the center of the ferroelectric pattern 300.

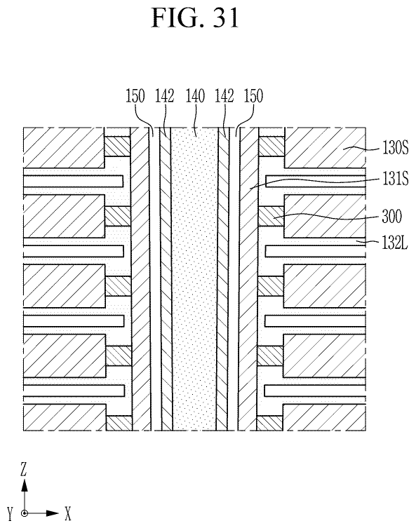

Next, referring to FIG. 31, a first gate insulating layer 132L is formed in an area from which the plurality of gate sacrificial insulating layers 132S are removed. The first gate insulating layer 132L may include a silicon oxide, a silicon nitride, a silicon oxynitride, a low dielectric constant material having a smaller dielectric constant than the silicon oxide, or a combination thereof. Referring to FIG. 31, the first gate insulating layer 132L may be formed on the surfaces of the sacrificial insulating layer 130S, the ferroelectric pattern 300, and the sacrificial electrode layer 131S.

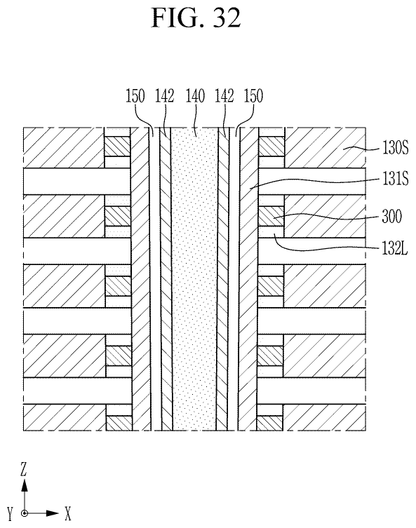

Next, referring to FIG. 32, the first gate insulating layer 132L is etched. As shown in FIG. 32, only the first gate insulating layer 132L filling the step between the ferroelectric pattern 300 and the sacrificial insulating layer 130S remains, and the remaining first gate insulating layer 132L may be etched. Therefore, as illustrated in FIG. 32, the upper surface of the first gate insulating layer 132L may be disposed at the same level as the upper surface of the sacrificial insulating layer 130S. In addition, the lower surface of the first gate insulating layer 132L may be disposed at the same level as the lower surface of the sacrificial insulating layer 130S. In the present step, the side surface of the sacrificial insulating layer 130S may be exposed through etching.

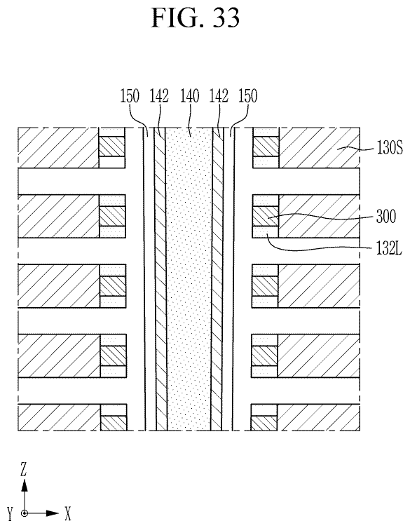

Next, referring to FIG. 33, the sacrificial electrode layer 131S is removed. Since the sacrificial electrode layer 131S includes a material having an etch selectivity with respect to the sacrificial insulating layer 130S, only the sacrificial electrode layer 131S may be removed.

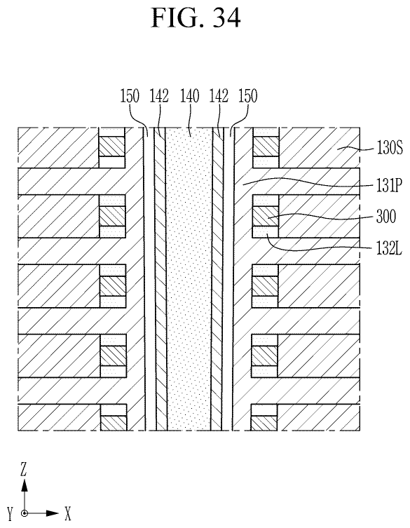

Next, referring to FIG. 34, a conductive electrode layer 131P is formed in a space in which the sacrificial electrode layer 131S is removed. As shown in FIG. 31, the conductive electrode layer 131P may be formed to fill a space from which the sacrificial electrode layer 131S is removed and a space from which the gate sacrificial insulating layer 132S is removed in the previous step.

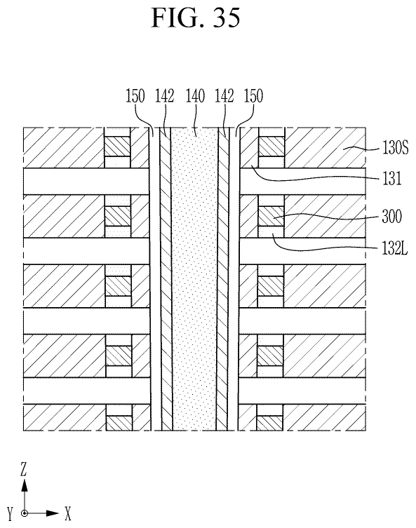

Next, referring to FIG. 35, the conductive pattern 131 is formed by etching the conductive electrode layer 131P. A plurality of conductive patterns 131 may be disposed to be spaced apart from each other in the third direction (Z direction) by etching in the present step.

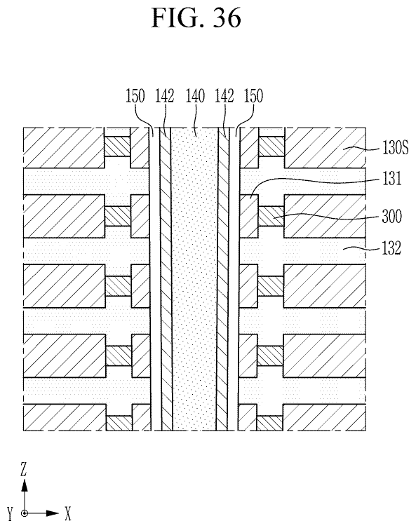

Next, referring to FIG. 36, the gate insulating layer 132 is formed in the space between the sacrificial insulating layers 130S. In this case, the gate insulating layer 132 may include the same material as the first gate insulating layer 132L formed in the previous step, and may be connected as one to the first gate insulating layer 132L formed in the previous step to configure the gate insulating layer 132.

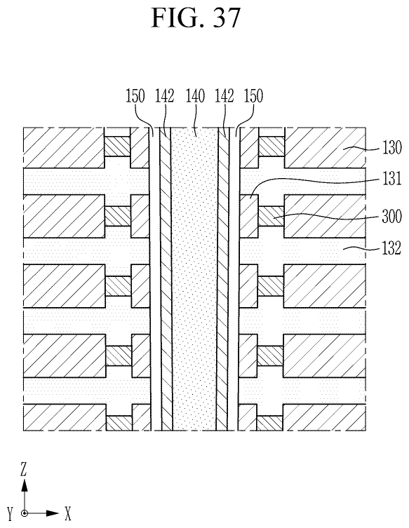

Next, referring to FIG. 37, the plurality of sacrificial insulating layers 130S are removed, and the plurality of gate electrodes 130 are formed in the space in which the plurality of sacrificial insulating layers 130S are removed. For example, after removing the plurality of sacrificial insulating layers 130S using an etching process, metal materials such as tungsten (W), copper (Cu), aluminum (Al), and the like may be deposited to form the plurality of gate electrodes 130.

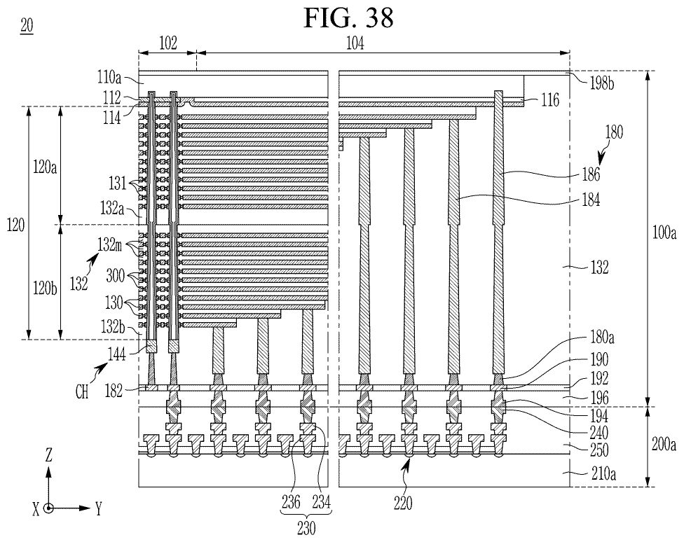

Hereinafter, a semiconductor device according to another embodiment will be described below. FIG. 38 illustrates a schematic cross-sectional view of a semiconductor device 20 according to an additional embodiment.

Referring to FIG. 38, the semiconductor device 20 according to the embodiment may have a chip-to-chip (C2C) structure bonded by a wafer bonding method. That is, after manufacturing a lower chip including a circuit area 200a formed on a first substrate 210a and then an upper chip including a cell area 100a formed on a second substrate 110a, the semiconductor device 20 may be manufactured by bonding them.

The circuit area 200a may include the first substrate 210a, a circuit element 220, a first wiring portion 230, and a first bonding structure 240 electrically connected to the first wiring portion 230 and disposed on a surface facing the cell area 100a. An area other than the first bonding structure 240 on a surface facing the cell area 100a may be covered by a first insulating layer 250.

The cell area 100a may include the second substrate 110a, a gate stacked structure 120, a channel structure CH, a second wiring portion 180, and a second bonding structure 194 electrically connected to the second wiring portion 180 and disposed on a surface facing the circuit area 200a. An area other than the second bonding structure 194 may be covered by an insulating layer 196.

In the embodiment, the second substrate 110a may be a semiconductor substrate including a semiconductor material. For example, the second substrate 110a may be a semiconductor substrate made of a semiconductor material, or it may be a semiconductor substrate with a semiconductor layer formed on a base substrate. For example, the second substrate 110a may be configured of monocrystalline or polycrystalline silicon, germanium, silicon-germanium, silicon-on-insulator, or germanium-on-insulator. Alternatively, the second substrate 110a may be configured of an insulating layer or a support member including an insulating material. After the cell area 100a is bonded to the circuit area 200a, the semiconductor substrate provided in the cell area 100a may be removed, and the support member including an insulating layer or an insulating material may be formed.

In the embodiment, the gate stacked structure 120 may be sequentially stacked on the lower portion of the second substrate 110a on the drawing, and may be disposed in a structure in which the gate stacked structure 120 shown in FIG. 1 is vertically inverted. In addition, the channel structure CH passing through the gate stacked structure 120 may also have a structure in that the channel structure CH shown in FIG. 2 is vertically inverted. Accordingly, when the channel structure CH is viewed in a cross sectional view, it may have an inclined side surface so that its width narrows from the circuit area 200a toward the second substrate 110a. In addition, a channel pad 144 and the second wiring portion 180 disposed on the gate stacked structure 120 may be disposed adjacent to the circuit area 200a.

For example, the first bonding structure 240 and/or the second bonding structure 194 may be made of aluminum, copper, tungsten, or an alloy thereof. For example, the first and second bonding structures 240 and 194 may include copper, so that the cell area 100a and the circuit area 200a may be bonded (for example, bonded by direct contact) by copper-to-copper bonding.

Although FIG. 38 illustrates that the gate stacked structure 120 includes a plurality of gate stacked structures, differently, it may include one or three or more gate stacked structures. Except for those described separately, the description of the gate stacked structure 120 and the channel structure CH described with reference to FIG. 1 to FIG. 9 may be applied as it is. In FIG. 38, an electrical connection structure between the channel structure CH and the horizontal conductive layers 112 and 114 and/or the second substrate 110a is illustrated to be the same as that in FIG. 2. The embodiment is not limited thereto, and the electrical connection structure between the channel structure CH and the horizontal conductive layers 112 and 114 and/or the second substrate 110a may be variously changed.

The semiconductor device 20 according to one example may include an input/output pad (not shown) and an input/output connection wiring (not shown) electrically connected thereto. The input/output connection wiring may be electrically connected to a portion of the second bonding structure 194. The input/output pad may be disposed, for example, on the insulating film 198b covering the outer surface of the second substrate 110a. In some embodiments, a separate input/output pad electrically connected to the circuit area 200a may be provided.

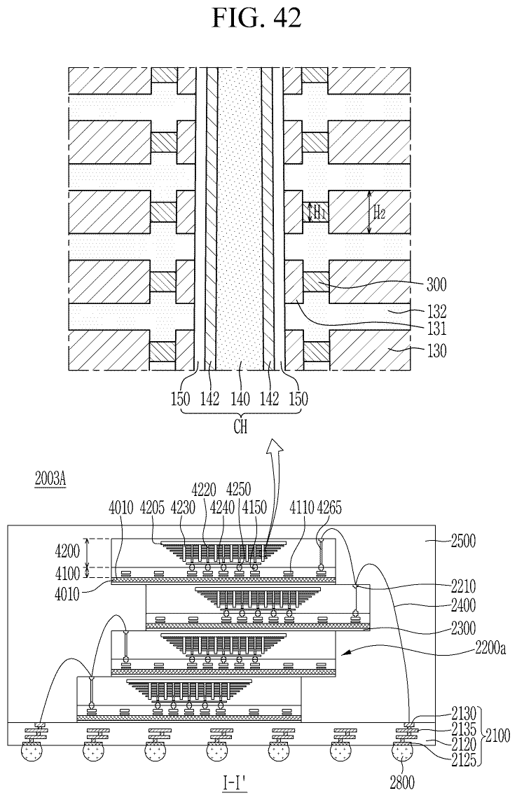

For example, the circuit area 200a and the cell area 100a may be portions corresponding to a first structure 1100F and a second structure 1100S of a semiconductor device 1100 included in an electronic system 1000 illustrated in FIG. 39, respectively. Alternatively, the circuit area 200a and the cell area 100a may be areas including a first structure 4100 and a second structure 4200 of a semiconductor chip 2200a illustrated in FIG. 42, respectively.

FIG. 39 schematically illustrates an electronic system including a semiconductor device according to an example embodiment.

Referring to FIG. 39, an electronic system 1000 according to an embodiment may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive device (SSD device), a universal serial bus (USB), a computing system, a medical device, or a communication device including one or more semiconductor devices 1100.

The semiconductor device 1100 may be a non-volatile memory device. The semiconductor device 1100 may include a first structure 1100F and a second structure 1100S on the first structure 1100F. In an example embodiment, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, respective memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied according to embodiments.

In an example embodiment, the lower transistors LT1 and LT2 may include a ground selection transistor, and the upper transistors UT1 and UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 extending from the first structure 1100F to the second structure 1100S. The bit line BL may be electrically connected to the page buffer 1120 through a second connection wiring 1125 extending from the first structure 1100F to the second structure 1100S.

In the first structure 1100F, the decoder circuit 1110 and the page buffer 1120 may perform a control operation on at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending from the first structure 1100F to the second structure 1100S.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. Through the NAND interface 1221, a control command for controlling the semiconductor device 1100, data to be written to the memory cell transistor MCT of the semiconductor device 1100, data to be read from the memory cell transistor MCT of the semiconductor device 1100, and the like may be transmitted. The host interface 1230 may provide a communication function between the electronic system 1000 and an external host. When a control command is received from an external host through the host interface 1230, the processor 1210 may control the semiconductor device 1100 in response to the control command.

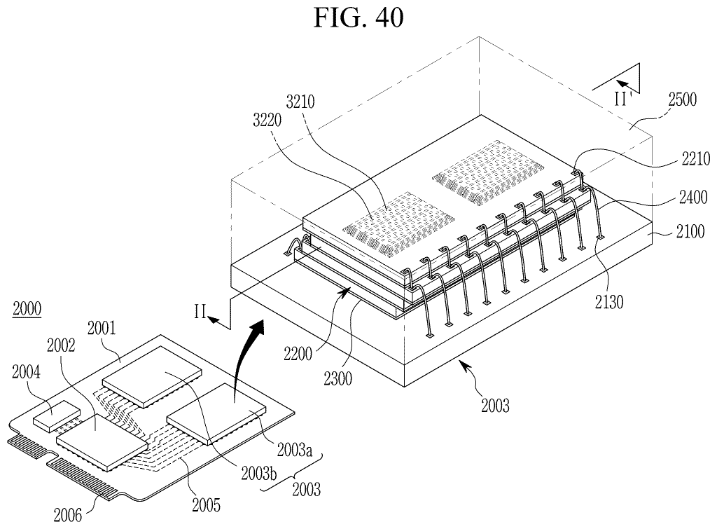

FIG. 40 illustrates a schematic perspective view of an electronic system including a semiconductor device according to an example embodiment.

Referring to FIG. 40, an electronic system 2000 according to an embodiment may include a main substrate 2001, a controller 2002 mounted on the main substrate 2001, one or more semiconductor packages 2003, and a DRAM 2004. The semiconductor package 2003 and the DRAM 2004 may be connected to the controller 2002 by a wiring pattern 2005 formed on the main substrate 2001.

The main substrate 2001 may include a connector 2006 including a plurality of pins coupled to an external host. The number and disposition of the plurality of pins in the connector 2006 may vary depending on the communication interface between the electronic system 2000 and the external host. In an example embodiment, the electronic system 2000 may communicate with an external host depending on one of interfaces such as universal serial bus (USB), peripheral component interconnect express (PCI-Express), serial advanced technology attachment (SATA), and M-Phy for universal flash storage (UFS). In an example embodiment, the electronic system 2000 may operate with power supplied from an external host through the connector 2006. The electronic system 2000 may further include a power management integrated circuit (PMIC) that distributes power supplied from the external host to the controller 2002 and the semiconductor package 2003.

The controller 2002 may write data to the semiconductor package 2003 or read data from the semiconductor package 2003, and may improve the operating speed of the electronic system 2000.

The DRAM 2004 may be a buffer memory for alleviating a difference in speed between the semiconductor package 2003 which is a data storage space and an external host. The DRAM 2004 included in the electronic system 2000 may operate as a kind of cache memory, and may provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a semiconductor chip 2200 on the package substrate 2100, an adhesive layer 2300 disposed on a lower surface of each of the semiconductor chips 2200, a connection structure 2400 electrically connecting the semiconductor chip 2200 to the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 in FIG. 39. Each semiconductor chip 2200 may include a gate stacked structure 3210 and a channel structure 3220. Each semiconductor chip 2200 may include the semiconductor devices described with reference to the previous drawings.

In an example embodiment, the connection structure 2400 may be a bonding wire electrically connecting the input/output pad 2210 to the package upper pad 2130. Accordingly, in each of the first and second semiconductor packages 2003a and 2003b, the semiconductor chips 2200 may be electrically connected to each other using a bonding wiring method, and may be electrically connected to the package upper pad 2130 of the package substrate 2100. In some embodiments, in each of the first and second semiconductor packages 2003a and 2003b, the semiconductor chips 2200 may be electrically connected to each other by a connection structure including a through silicon via (TSV) instead of the connection structure 2400 that uses the bonding wiring method.

In an example embodiment, the controller 2002 and the semiconductor chip 2200 may be included in one package. For example, the controller 2002 and the semiconductor chip 2200 may be mounted on a separate interposer substrate different from the main substrate 2001, and the controller 2002 and the semiconductor chip 2200 may be connected to each other by wiring formed on the interposer substrate.

FIG. 41 and FIG. 42 respectively illustrate a schematic cross-sectional view of a semiconductor package according to an example embodiment. FIG. 41 and FIG. 42 respectively illustrate an example embodiment of the semiconductor package 2003 of FIG. 40, and conceptually illustrate an area taken along a cutting line II-II′ of the semiconductor package 2003 of FIG. 40.

Referring to FIG. 41, in the semiconductor package 2003, the package substrate 2100 may be a printed circuit board. The package substrate 2100 may include a package substrate body portion 2120, a package upper pad 2130 disposed on an upper surface of the package substrate body portion 2120, a lower pad 2125 disposed on a lower surface of the package substrate body portion 2120 or exposed through the lower surface, and an internal wiring 2135 electrically connecting the upper pad 2130 and the lower pad 2125 inside the package substrate body portion 2120. The upper pad 2130 may be electrically connected to the connection structure 2400. The lower pad 2125 may be connected to the wiring pattern 2005 of the main substrate 2010 of the electronic system 2000 as shown in FIG. 40 through a conductive connection portion 2800.

The semiconductor chip 2200 may include a semiconductor substrate 3010 and a first structure 3100 and a second structure 3200 sequentially stacked on the semiconductor substrate 3010, respectively. The first structure 3100 may include a peripheral circuit area including a peripheral wiring 3110. The second structure 3200 may include a common source line 3205, a gate stacked structure 3210 on the common source line 3205, a channel structure 3220 and a separation structure 3230 penetrating the gate stacked structure 3210, a bit line 3240 electrically connected to the channel structure 3220, and a gate connection wiring electrically connected to the word line (WL in FIG. 39) of the gate stacked structure 3210.

In the semiconductor chip 2200 or semiconductor device according to the embodiment, since the ferroelectric pattern 300 disposed around the channel structure CH is included and the thickness H1 of the ferroelectric pattern 300 is thinner than the thickness H2 of the gate electrode 130, the capacitance of the ferroelectric pattern 300 may be reduced and the reliability of the semiconductor device may be improved.

Each semiconductor chip 2200 may include a through wiring 3245 electrically connected to the peripheral wiring 3110 of the first structure 3100 and extending into the second structure 3200. The through wiring 3245 may penetrate the gate stacked structure 3210, and may be further disposed outside the gate stacked structure 3210. Each semiconductor chip 2200 may further include an input/output connection wiring 3265 electrically connected to the peripheral wiring 3110 of the first structure 3100 and extending into the second structure 3200 and an input/output pad 2210 electrically connected to the input/output connection wiring 3265.

In an example embodiment, a plurality of semiconductor chips 2200 in the semiconductor package 2003 may be electrically connected to each other by the connection structure 2400 in the form of a bonding wire. As another example, a plurality of semiconductor chips 2200 or a plurality of portions configuring the semiconductor chips 2200 may be electrically connected by a connection structure including a through electrode.

Referring to FIG. 42, in a semiconductor package 2003A, each of semiconductor chips 2200a may include a semiconductor substrate 4010, a first structure 4100 on the semiconductor substrate 4010, and a second structure 4200 bonded to the first structure 4100 by a wafer bonding method on the first structure 4100.

The first structure 4100 may include a peripheral circuit area including a peripheral wiring 4110 and a first bonding structure 4150. The second structure 4200 may include a common source line 4205, a gate stacked structure 4210 between the common source line 4205 and the first structure 4100, a channel structure 4220 and a separation structure 4230 penetrating the gate stacked structure 4210, and a second bonding structure 4250 electrically connected to the channel structure 4220 and the word line (WL in FIG. 39, hereinafter the same) of the gate stacked structure 4210. For example, the second junction structure 4250 may be electrically connected to the channel structure 4220 and the word line WL, respectively, through a bit line 4240 electrically connected to the channel structure 4220 and a gate connection wiring electrically connected to the word line WL. The first bonding structure 4150 of the first structure 4100 and the second bonding structure 4250 of the second structure 4200 may be bonded while being in contact with each other. Bonded portions of the first bonding structure 4150 and the second bonding structure 4250 may be made of, for example, copper (Cu).

In the semiconductor chip 2200 or semiconductor device according to the embodiment, since the ferroelectric pattern 300 disposed around the channel structure CH is included and the thickness H1 of the ferroelectric pattern 300 is thinner than the thickness H2 of the gate electrode 130, the capacitance of the ferroelectric pattern 300 may be reduced and the reliability of the semiconductor device may be improved.

Each of the semiconductor chips 2200a may further include an input/output pad 2210 and an input/output connection wiring 4265 under the input/output pad 2210. The input/output connection wiring 4265 may be electrically connected to a portion of the second bonding structure 4250.

In the embodiment, a plurality of semiconductor chips 2200a in the semiconductor package 2003A may be electrically connected to each other by the connection structure 2400 in the form of a bonding wire. As another example, a plurality of semiconductor chips 2200 or a plurality of portions configuring the semiconductor chips 2200 may be electrically connected by a connection structure including a through electrode.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device comprising:
a substrate;
a gate stacked structure including a plurality of interlayer insulating layers and a plurality of gate electrodes alternately stacked on the substrate;
a channel structure extending along a first direction through the gate stacked structure and connected to the substrate;
a plurality of conductive patterns surrounding the channel structure and spaced apart from each other at different levels along the first direction; and
a plurality of ferroelectric patterns spaced apart from each other and each respectively surrounding the conductive patterns at each of the different levels along the first direction,
wherein, at each of the different levels along the first direction, a ferroelectric pattern is disposed between a conductive pattern and a gate electrode in a radial direction of the channel structure, and
wherein, at each of the different levels along the first direction, a thickness of the ferroelectric pattern in the first direction is thinner than a thickness in the first direction of the gate electrode.

2. The semiconductor device of claim 1, wherein, at each of the different levels along the first direction, a thickness of the ferroelectric pattern in the first direction is thinner than a thickness of the conductive pattern in the first direction.

3. The semiconductor device of claim 1, wherein, at each of the different levels along the first direction, a thickness of the ferroelectric pattern in the first direction is 50% to 70% of a thickness of the gate electrode in the first direction.

4. The semiconductor device of claim 1, wherein, at each of the different levels along the first direction, a partial area of the interlayer insulating layer overlaps the gate electrode and the conductive pattern in the radial direction of the channel structure.

5. The semiconductor device of claim 1, wherein, at each of the different levels along the first direction, a thickness of the conductive pattern in the first direction and a thickness of the gate electrode in the first direction are the same.

6. The semiconductor device of claim 5, wherein a distance between the conductive patterns adjacent to each other in the first direction is shorter than a distance between the ferroelectric patterns adjacent to each other in the first direction.

7. The semiconductor device of claim 1, wherein, at each of the different levels along the first direction, a thickness of the conductive pattern in the first direction is thicker than a thickness of the gate electrode in the first direction.

8. The semiconductor device of claim 7, wherein, at each of the different levels along the first direction, a thickness in the first direction of the interlayer insulating layer overlapping the conductive pattern in the first direction is thinner than a thickness in the first direction of the interlayer insulating layer overlapping the gate electrode in the first direction.

9. The semiconductor device of claim 1, wherein upper and lower surfaces of the plurality of ferroelectric patterns are flat surfaces with respect to an upper surface of the substrate.

10. The semiconductor device of claim 1, wherein upper and lower surfaces of the plurality of ferroelectric patterns include concave curved surfaces.

11. A semiconductor device comprising:
a substrate;
a gate stacked structure including a plurality of interlayer insulating layers and a plurality of gate electrodes alternately stacked on the substrate;
a channel structure extending along a first direction through the gate stacked structure and connected to the substrate;
a plurality of conductive patterns surrounding the channel structure and spaced apart from each other at different levels along the first direction; and
a plurality of ferroelectric patterns spaced apart from each other and each respectively surrounding and in contact with the conductive patterns at each of the different levels along the first direction,
wherein, at each of the different levels along the first direction, a lower surface of the ferroelectric pattern is disposed farther from the substrate than a lower surface of the conductive pattern contacting the ferroelectric pattern, and
wherein, at each of the different levels along the first direction, an upper surface of the ferroelectric pattern is disposed closer to the substrate than an upper surface of the conductive pattern contacting the ferroelectric pattern.

12. The semiconductor device of claim 11, wherein, at each of the different levels along the first direction,
the ferroelectric pattern is disposed between the conductive pattern and the gate electrode in a radial direction of the channel structure,
a lower surface of the ferroelectric pattern is disposed farther from the substrate than a lower surface of the gate electrode contacting the ferroelectric pattern, and
an upper surface of the ferroelectric pattern is disposed closer to the substrate than an upper surface of the gate electrode contacting the ferroelectric pattern.

13. The semiconductor device of claim 11, wherein, at each of the different levels along the first direction, a thickness of the ferroelectric pattern in the first direction is thinner than a thickness in the first direction of the conductive pattern contacting the ferroelectric pattern.

14. The semiconductor device of claim 11, wherein, at each of the different levels along the first direction, a thickness of the ferroelectric pattern in the first direction is thinner than a thickness in the first direction of the gate electrode contacting the ferroelectric pattern.

15. The semiconductor device of claim 14, wherein, at each of the different levels along the first direction, the thickness of the ferroelectric pattern in the first direction is 50% to 70% of the thickness in the first direction of the gate electrode contacting the ferroelectric pattern.

16. The semiconductor device of claim 11, wherein, at each of the different levels along the first direction, a thickness of the conductive pattern in the first direction and a thickness of the gate electrode in the first direction.

17. The semiconductor device of claim 11, wherein, at each of the different levels along the first direction, a thickness of the conductive pattern in the first direction is thicker than a thickness of the gate electrode in the first direction.

18. An electronic system comprising:
a main substrate;
a semiconductor device on the main substrate; and
a controller electrically connected to the semiconductor device on the main substrate,
the semiconductor device includes
a substrate,
a gate stacked structure including a plurality of interlayer insulating layers and a plurality of gate electrodes alternately stacked on the substrate,
a channel structure extending along a first direction through the gate stacked structure and connected to the substrate,
a plurality of conductive patterns surrounding the channel structure and spaced apart from each other at different levels along the first direction, and
a plurality of ferroelectric patterns spaced apart from each other and each respectively surrounding the conductive patterns at each of the different levels along the first direction,
wherein, at each of the different levels along the first direction, a ferroelectric pattern is disposed between a conductive pattern and a gate electrode in a radial direction of the channel structure, and
wherein, at each of the different levels along the first direction, a thickness of the ferroelectric pattern in the first direction is thinner than a thickness in the first direction of the gate electrode.

19. The semiconductor device of claim 18, wherein, at each of the different levels along the first direction, a thickness of the ferroelectric pattern in the first direction is thinner than a thickness of the conductive pattern in the first direction.

20. The semiconductor device of claim 18, wherein, at each of the different levels along the first direction, a thickness of the ferroelectric pattern in the first direction is 50% to 70% of a thickness of the gate electrode in the first direction.
